(19) United States
(12) Patent Application Publication
(10) Pub. No.: US 2012/0132891 A1
(43) Pub. Date: May 31, 2012

(54) PRECISION QUANTUM DOT CLUSTERS

(75) Inventors: Leonard F. Pease, III, Bountiful, UT (US); Jeeseong C. Hwang, Gaithersburg, MD (US)

(73) Assignee: UNIVERSITY OF UTAH RESEARCH FOUNDATION, Salt Lake City, UT (US)

(21) Appl. No.: 13/183,243

(22) Filed: Jul. 14, 2011

Related U.S. Application Data
(60) Provisional application No. 61/364,223, filed on Jul. 14, 2010.

(51) Int. Cl. H01L 31/0352; H01L 29/66; H01L 21/20

(52) U.S. Cl. 257/21; 438/478; 257/15; 257/E21.09; 257/E29.168; 257/E31.033

(57) ABSTRACT

Precision quantum dot clusters and methods for producing and tuning quantum dot clusters are described herein. Also described herein are materials and devices, including photovoltaic devices, that may include one or more quantum dot clusters.

### RELATED APPLICATIONS

This application claims the benefit of U.S. Provisional Application No. 61/364,223, filed on Jul. 14, 2010. The entire contents of which is incorporated by reference herein.

### TECHNICAL FIELD

This disclosure is related to precision quantum dot clusters and methods for producing and intentionally tuning the composition of quantum dot clusters. This disclosure is also related to materials, devices, environments, and manufacturing processes that may include the use of precision quantum dot clusters.

### BACKGROUND

Photonic devices have the potential for use in a wide variety of applications ranging from energy harvest and production, communications, bioterrorism detection, quantum computing, display architectures, low power lighting, cameras, computer security, solid state lighting, catalytic systems, biomedical imaging, optical devices, spintronics, etc. Each of these useful arts requires continuing advances in new materials, including those derived from nanotechnology. In nanotechnology, nanoscale “building blocks” with at least one dimension less than 100 nm are assembled into functional elements by directed or self assembly. An exemplary improvement in nanotechnology has been in the field of nanooptics with the development of semiconducting nanocrystals or quantum dots (QDs). A quantum dot is a (nano) particle or portion of a larger material that exhibits quantum confinement in three dimensions. Quantum confinement occurs when a characteristic length of a material remains less than the Bohr radius of the material. QDs may be colloidal, grown in situ on patterned or structured substrates, or fabricated in aerosols. Certain QDs are made from silicon, III-V, II-VI or other semiconductors. Alternatively, QDs may be generated by selective doping of other materials. For QD sensitized photovoltaic or solar cells, an important attribute may be the achievement of improved efficiencies by generating multiple excitons (electron-hole pairs stimulated by photon absorption) within an individual QD.

QDs may be used in certain devices because they harvest and convert photonic energy to electronic energy and vice versa. The efficiency of these devices is typically associated with the chemistry and atomic stoichiometry of the QDs, their density and their location within the device. For example, past efforts to improve the quantum yield of these materials have focused on increasing energy collection and conversion efficiency of individual QDs through improved materials selection and doping. In each case, however, new materials chemistry and synthesis is required to achieve new QD properties. The lack of more efficient ways to tune optical, photonic, physical or electrical properties of device elements without resorting to novel materials synthesis in each case, remains a long standing need.

Clusters of QDs may possess distinct properties from individual QDs. These clusters of QDs may include, for example, random aggregates of QDs, randomly assembled QD clusters near pinned or unpinned contact lines of evaporating drops on surfaces, randomly sintered QDs, or labyrinthine QDs, all containing an uncontrolled number of QDs per cluster. In the absence of selective means to precisely tune the composition, the properties of these aggregates are stochastic, not repeatable, not useful in a manufacturing environment, and generally not reliable. It would be desirable to be able to selectively tune the composition of QD clusters and to reliably and predictably produce desired optical, photonic, structural, and electronic properties of the QD clusters.

Colloidal or aerosol synthesis of QD clusters represents an efficient and cost effective means to generate quantum confined materials. However, assembling these particles into clusters and useful nanoscale elements may require chemical or biological linkers that can induce separation between one QD and one or more neighboring QDs, neighboring photonic particles, surfaces, interfaces or surrounding media. These separations interfere with exciton transport between one QD with one or more neighboring QDs, neighboring photonic particles, surfaces, and interfaces or surrounding media. The ability to assemble colloidal or aerosol synthesized QDs without the use of chemical or biological linkers remains a long standing need.

Many QDs are crystalline in structure and many are elongated in shape as the length of one or two crystalline dimensions exceeds that of other(s). This leads to additional degrees of freedom in the final configuration of the QDs when clustered relative to spherical QDs. Unlike QDs grown in situ on or in patterned substrates, colloidal QDs are difficult to align, and even more so when arranged into clusters. This drawback has significantly limited their utility and incorporation in commercially relevant devices. As individual QDs have quantized structures similar to individual atoms, clustered QDs have quantized structures similar to molecules. It follows then that the relative orientation of the particles within a cluster is intimately related to the way that they exchange energy within the cluster and within their local environment. However, outside of painstakingly arranging each QD individually on a substrate, which is not commercially feasible, the means to arrange particles within a cluster is severely limited.

### DESCRIPTION OF DRAWINGS

FIG. 1: Schematic of electrospray-differential mobility analyzer-condensation particle counter/electrostatic deposition (ES-DMA-CPC/ED) system used to produce clusters of QDs via the reliable electrospray droplet induced clustering and purification (REDICAP) technique.

FIG. 2: Schematic of a low background sandwich assay using clustered QDs in which the cluster is labeled with a binding agent (e.g. an antibody). Before binding (a) to an antigen (e.g. bacteria) captured on a metallic surface, the cluster emission is at a distinct wavelength from adsorption or is time delayed to minimize background interference. After binding (b) to the antigen, emission is suppressed by the FRET effect. Panels (c) and (d) represent clusters within a nanoparticle decorated with a binding agent (e.g. an antibody) before and after antigen binding.

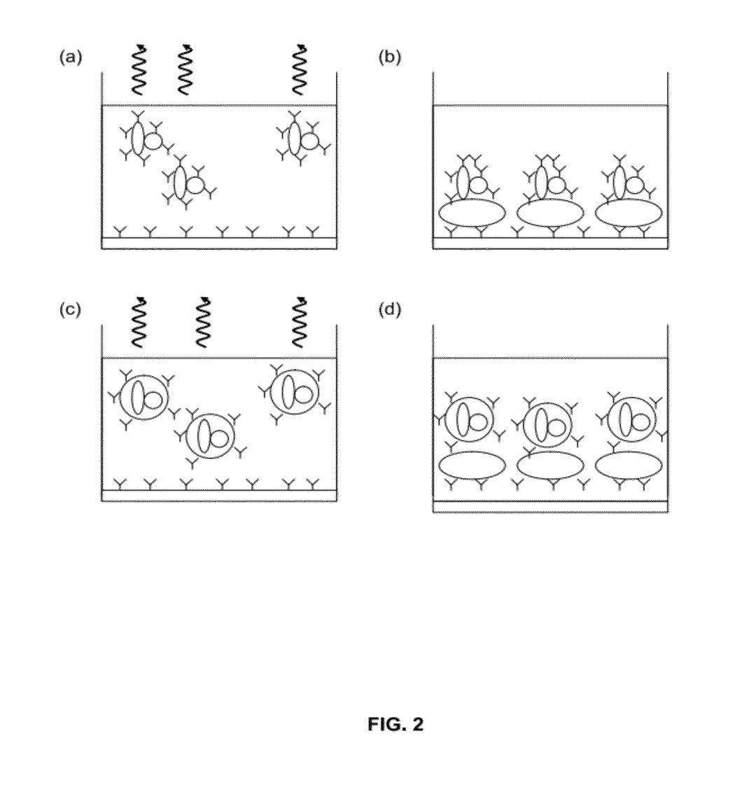

FIG. 3: Clusters composed of rod-like QDs (each approximately 10 nm in length and approximately 3 nm in diameter) formed using the REDICAP method.

FIG. 4: The intensity, spectrum, and lifetime of QD clusters.

FIG. 5: The spectrum of (a) one QD per QD cluster, (b) two QDs per QD cluster, and (c) three QDs per QD cluster.

FIG. 6: Depiction of (a) the three projected areas, Aᵢ, used to determine the mobility of a close packed trimeric cluster, (b) formulas used to quantify the center-to-center separations, hᵢ, and (c) expressions used to determine the overlap area, Aₒᵥ, (darkest region) for each of the four possible overlap scenarios for two circles with diameters d_{A} and d_{B} (d_{A}≦d_{B}) and centers separated by distance s. The two intermediate overlap conditions are required as functions are single valued.

FIG. 7: Comparison of size distributions calculated using the complete projected area analysis (circles) and the simplified analysis using average diameters with proportionality constants (triangles) for three nominally 6 nm particles arranged in trimeric clusters for d_{drop}=150 nm, σ_{drop}/d_{drop}=⅙, σₙₚ/dₙₚ=0.1 and 10000 droplets at a concentration of 4.6×10¹⁴ particles/mL.

FIG. 8: (a) Cluster yield from 1000 droplets, each 150 nm in diameter, versus concentration for monomers (filled circles), dimers (filled triangles), trimers (filled circles), tetramers (open circles), pentamers (open triangles) and clusters composed of six or more particles (filled squares) for (σ_{drop}/d_{drop}=0, dₙₚ=6 nm, and σₙₚ/dₙₚ=0.1. (b) Fractional yield of clusters versus the scaled concentration (i.e. the concentration divided by the concentration scale of Eq. 2 with n=1 and α=1) for 150 nm (small symbols), 200 nm (medium symbols), and 250 nm (large symbols) droplets for σ_{drop}/d_{drop}=0, dₙₚ=6 nm, and σₙₚ/dₙₚ=0.1. (c) Fractional yield of clusters versus the scaled concentration for 250 nm droplets for (σ_{drop}/d_{drop}=0 (small symbols), (σ_{drop}/d_{drop}=⅙ (medium symbols), and (σ_{drop}/d_{drop}=⅓ (large symbols) with dₙₚ=6 nm and σₙₚ/dₙₚ=0.1. (d) Data of panel b represented with a linear abscissa scale.

FIG. 9: Droplet size distributions for ionic strengths of 2 mM (solid) and 20 mM (long dash) obtained from solutions of sucrose in ammonium acetate electrosprayed from a 25 μm capillary with a flow rate of approximately 66 mL/min and sheath gas of 0.2 L/min of CO₂ and 1.0 L/min air.

FIG. 10: ES-DMA size distribution of QDs at 0.4 μM (2.4×10¹⁴ particles/mL) in 11 mmol/L acetic acid.

FIG. 11: (a) Cut-off concentration at which 1% (circle) and 5% (triangle) of the clusters are not monomers versus droplet diameter for σₙₚ/dₙₚ=⅙ (filled symbols) and σₙₚ/dₙₚ=0 (empty symbols) with dₙₚ=6 nm and σₙₚ/dₙₚ=0.1. The curve represents the concentration predicted by the scaling relation (n=α=1). (b) Concentrations that maximize the production of dimers (circle) and trimers (triangle) versus droplet diameter for σₙₚ/dₙₚ=⅙ (filled symbols) and σₙₚ/dₙₚ=0 (empty symbols) with dₙₚ=6 nm and σₙₚ/dₙₚ=0.1. The curves represent the scaling prediction for monomers (n=α=1, solid), dimers (n=2, α=1, long dash), and trimers (n=3, α=1, short dash).

FIG. 12: (a) Selectivity for dimers (filled symbols) and trimers (empty symbols) as a function of the ratio of the standard deviation to mean of the nanoparticle diameter distribution for 6 nm (triangles), 14 nm (squares), and 22 nm (circles) diameters with d_{drop}=150 nm and (σ_{drop}/d_{drop}=⅙ at a nanoparticle concentration of 6.8·10¹⁴ particles/mL. (b) Selectivity for dimers (filled symbols) and trimers (empty symbols) versus the ratio of the standard deviation to mean of the droplet diameter distribution for 150 nm (blue squares), 225 nm (red triangles), 250 nm (green diamonds), and 350 nm (purple circles) diameters for dₙₚ=6 nm and σₙₚ/dₙₚ=⅓ at a concentration of 6.8×10¹⁴ particles/mL.

FIG. 13: (a) Ratio of calculated mobility diameter to QD particle diameter (=3 nm) versus angle between two homogeneous QDs for three lengths as labeled. Calculated mobility diameter versus angle for QD particles (b) 10 nm and (c) 20 nm in diameter with lengths as labeled. The peak mobility diameter occurs at θ=π/2 where the two QDs are perpendicular to each other.

FIG. 14: Size distributions of from ES-DMA with CPC detection. (a) QD-QD heterodimers prepared by combining a solution of QDs with a wavelength of 525 nm with a solution of QDs with a wavelength of 605 nm in ammonium acetate. The peaks and shoulders are as labeled. (b) QD-Au heterodimers prepared by combining a solution of QDs with a wavelength of 605 nm with a solution of 15 nm gold nanoparticles in ammonium acetate. The size distribution for QDs with a wavelength of 605 nm is also shown with peaks and shoulders are as labeled.

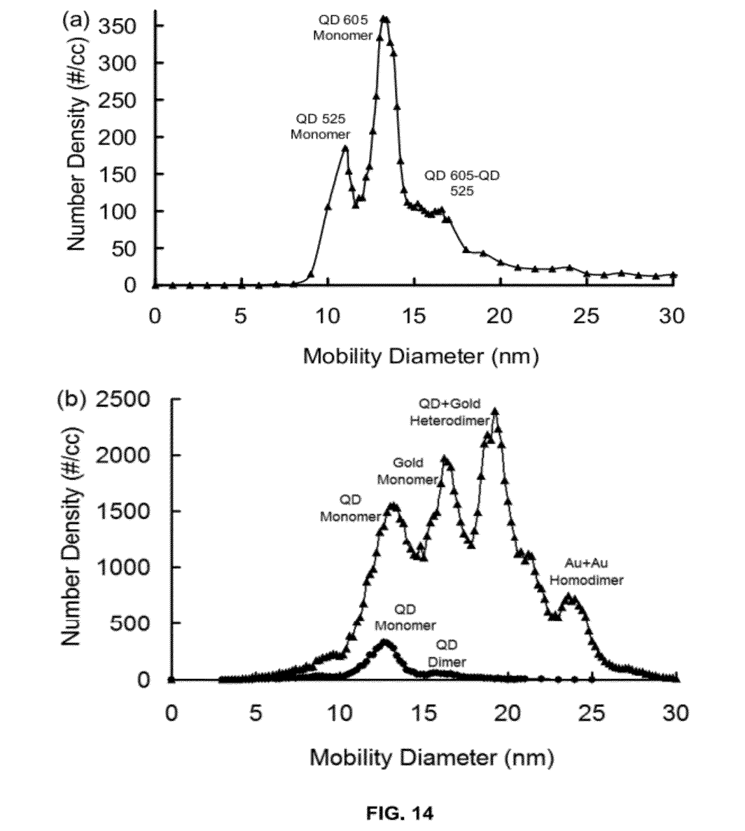

### DETAILED DESCRIPTION OF THE EMBODIMENTS

Precision clusters of nanoparticles comprising semiconductor nanocrystal QDs, or QD clusters, are described herein. Additionally, methods of making precision QD clusters are described herein. Moreover, methods of making and tuning QD clusters both in composition and orientation are disclosed herein. Furthermore, nanophotonic materials, devices, environment, and manufacturing processes comprising QD clusters are described herein. Also disclosed are QD clusters with particular optical, photonic, structural and electronic properties.

As used herein, the term “precision quantum dot clusters” refers to selected QD clusters with tuned composition and/or the production of a repeatable number of QD particles per QD cluster and/or mixture or ratio of types of QD particles within a QD cluster.

As used herein, the term “tune”, “tuned”, or “tuning” means to adjust the composition of a QD cluster for a selected size, purpose, operation, or activity. Tuning a QD cluster often improves the desired purpose, operation, or activity of the QD cluster. Tuning a QD cluster may also signify that the QD cluster composition is repeatable in the number of particles per cluster and in the mixture or ratio of particles within a cluster.

As used herein, “core-shell QDs” are QDs which are comprised of two chemical compositions with one composition residing in the center of the QD, while the second resides on the surface of the first forming a shell. Core-shell QDs may be categorized by the relative positions of their energy levels or band alignments.

As used herein, “colloidal QDs” are QD particulates that are dispersed within a continuous liquid medium. In one embodiment, to make well dispersed individual colloidal QDs a coating of an organic materials may be employed.

As used herein, “semiconducting QDs” are QDs comprising semiconducting materials. For example, semiconducting QDs may have a chemical composition comprising CdS, CdSe, CdTe, InP, GaAs, GaP, GaN, GaInP, core-shell InP/ZnCdSe2, Ge, Si PbSe, PbS, PbTe, core-shell CdTe/CdSe, CdSe/ZnS, InSb, and InAs, etc. Semiconductors are those materials with conductivities intermediate of those of metals and insulators and therefore have intermediate band gaps. In certain embodiments, some, but not all, semiconducting QDs are made out of elements in group IV of the periodic table, or combinations of elements from groups III and V, or combinations of elements from groups II and VI.

As used herein, “type-I band alignment” occurs in core-shell quantum dots. In type I band alignment, the conduction band of the core is at a lower electron energy level than that of the shell and the valance band of the core is at a higher electron energy level than that of the shell. In type I band alignment, both the electron and hole of the exciton reside preferentially within the core.

As used herein, “type-II band alignment” occurs in core-shell quantum dots. In type II band alignment, there are two possible alignments of the energy levels between core and shell. In the first possibility, the conduction band of the core is at a lower electron energy level than that of the shell and the valance band of the core is at a lower electron energy level than that of the shell. In this manner the electron of the exciton resides preferentially in the core, while the hole of the exciton resides preferentially within the shell. In the second possibility, the conduction band of the core is at a higher electron energy level than that of the shell and the valance band of the core is at a higher electron energy level than that of the shell. In this manner the electron of the exciton resides preferentially in the shell, while the hole of the exciton resides preferentially within the core.

As used herein, an “exciton” is a bound state of an electron and hole which are attracted to each other by the electrostatic Coulomb force.

As used herein, “upconverting quantum dots” (UCQDs) or interchangeably “upconverting nanoparticles” are QDs or nanoparticles that capture photons in the NIR range and, with double or multiple excitation, increase the emitted photon's energy into the visible region of the spectrum where other nanoparticles or quantum dots absorb efficiently.

As used herein, the term “coagulation concentration” is meant to be the concentration at which coagulation occurs on a laboratory time scale. Coagulation is the process by which individual QD particles clump together in the aerosol phase. (see Smoke, Dust, and Haze: Fundamentals of Aerosol Dynamics by Sheldon K. Friedlander, Oxford University Press, 2^{nd} Edition, 2000). As used herein, the term “coagulation time scale” refers to the time it takes for coagulation to occurs at a specific concentration.

As used herein, the term “aggregation” means the massing or clumping of QD particles together without predetermined number of QD particles per mass or clump. As used herein, the term “QD aggregates” refers to the mass or clumps of QDs formed because of aggregation.

As used herein, “sintering” means any method in which initially individual particles become a larger mass under the influence of thermal energy or heat. For example, sintering means the partial or complete merging of two or more individual QD particles within an already formed QD cluster. In certain embodiment, sintering may mean that only the QD shells completely or partially merge, or that QD cores partially merge.

The QDs, as described herein, are nanoparticles comprising semiconductor nanocrystals or/and particles. In one embodiment, the QDs disclosed herein are nanoparticles wherein more than one dimensional length is less than the Bohr radius of the material providing quantum confinement. The QDs as disclosed herein include a variety of compositions, sizes and types. In particular embodiments, the QDs disclosed herein may be rod-like QDs, rectangular QDs, triangular QDs, tetrapod QDs, ellipsoidal QDs, facetted QDs, spherical QDs, otherwise crystalline QDs, etc. In one embodiment, the QDs described herein range in size from approximately 2 nm to 50 nm. In one such embodiment, the QDs described herein range in size from about 2-5 nm, 2-10 nm, 5-10 nm, 5-15 nm, 10-20 nm, 15-25 nm, 20-30 nm, 25-35 nm, 30-40 nm, 35-45 nm, 40-50 nm, and 45-50 nm. In one embodiment, the QDs are comprised of only a core without a metal oxide or metal sulfide shell. In one embodiment, the QD clusters described herein comprise core-shell QDs that have type-I band alignment. In QDs with type-I band alignment, the electron energies across the band gap of the core lie between the energies of the shell, leaving the exciton's electron and hole within the core upon excitation.

In one embodiment, the QD clusters described herein comprise core-shell QDs that have type-II band alignment. In QDs having type-II band alignment, the energies of the core and shell are offset or staggered such that either the electron or hole moves into the shell. This separation substantially increases the QD's radiative lifetime, makes the energy levels sensitive to both core and shell thickness, and increases the time scale of electron-hole recombination to allow for increased migration of charge carriers to electrodes. In one embodiment, the QD clusters described herein comprise UCQDs or upconverting nanoparticles. As used herein, UCQDs capture photons in the NIR range and, with double or multiple excitation, increase the emitted photon's energy into the visible region of the spectrum where other nanoparticles absorb efficiently.

In one embodiment, the QDs are discrete particles that are suspended in an aerosol stream. In another embodiment, the QDs are colloidal QDs suspended in aqueous or liquid solutions. In another embodiment, QDs are discrete particles on a substrate.

The QDs as disclosed herein have many desirable characteristics for photonic devices, for example, (i) they may be less expensive than silicon-based photovoltaics; (ii) they have tunable, broad absorption spectra; (iii) when used to sensitize photovoltaic cells (i.e. quantum dot sensitized solar cells), they can have longer photoxidation lifetimes and higher quantum yields in the near infrared (NIR) than dye sensitized solar cells; (iv) a wide variety of QD types and dimensions are available to enable multiple charge carrier generation or multiple exciton generation and enhance the efficiency of photoelectric conversion within devices; and (v) the photoluminescence lifetime (PLT) of QDs may be adjusted to tune the rate of charge carrier recombination and improve device performance.

One attribute of the QDs disclosed herein is their ability to manipulate energy on the nanoscale. In one embodiment, two osculating QDs in intimate contact or bridged with a nanoscale conducting linker can be used to convert photonic energy (with wavelengths hundreds of nanometers long) into excitons with length scales of only a few nanometers before being converted back into the photonic energy. In one such embodiment, QD clusters as disclosed herein comprise two or more QDs osculating in intimate contact or bridged with a nanoscale conducting linker. In yet another embodiment, the QD clusters disclosed herein are separate and unlinked. Transport of the exciton from one QD to another or between parts of the QD is called excitonic energy transfer (EET). Energy can also be transferred on the nanoscale between pairs of nearby (but separate, unlinked) QDs via radiative dipole-dipole interactions, also known as Förster resonance energy transfer (FRET). In one embodiment, the QDs described herein may be used as nanocomponents to generate, transport, guide, focus, gate, store and detect photonic energy on the nanoscale.

In one embodiment, QD clusters disclosed herein may be used for photovoltaic applications. In certain embodiments, QD clustering comprises a “bottom-up” nanofabrication architecture to combine multiple QDs of distinct sizes and types to collect light across a broad range of the solar spectrum for photovoltaics. For example, combining semiconducting QDs (e.g., QDs with a chemical composition comprising CdS, CdSe, CdTe, InP, GaAs, GaP, GaN, GaInP, core-shell InP/ZnCdSe2, Ge, Si PbSe, PbS, PbTe, core-shell CdTe/CdSe, CdSe/ZnS, InSb, InAs, etc.) with upconverting UCQDs (e.g. lanthanide doped nanocrystals) may enhance the efficiency of energy conversion from low energy photons (e.g. in the NIR region of the solar spectrum) to higher energy charge carriers through energy transfer between heterogeneously paired QDs. The synthesis of QDs is described in Nozik, et al., Semiconductor Quantum Dots and Quantum Dot Arrays and Applications of Multiple Exciton Generation to Third-Generation Photovoltaic Solar Cells. Chem. Rev. 2010, 110, 6873-6890, which is incorporated by reference herein.

QD clustering may also be used in a nanofabrication architecture to combine multiple QDs of distinct sizes and types to tune the emission of lighting and display devices. In one embodiment, QD clusters containing 2, 3, 4 or more distinct QD particles, each of distinct size or/and chemical composition, can be incorporated within a lighting device. In one such embodiment, electrical stimulation of the QD cluster may provide an emission profile engineered to desired specifications. One particular embodiment may comprise the combination of certain QDs of distinct wavelength to produce soft white light emitting diodes. For example, one or more of the QDs in the cluster each emit at a certain wavelength to tune the desired color profile. Another embodiment can include an arrangement of QD clusters within pixels of a device to tune the light intensity emitted from the pixel. For example, for a given pixel one wavelength may be more weakly emitted than another/others and multiple QDs may be used to balance color and intensity relative to other wavelength(s). In still another embodiment, QD clusters may comprise two or more distinct QDs of two or more adjacent wavelengths to precisely tune the emission of a particular pixel.

The QD clusters as described herein may include one or more nanoparticles including multiple heterogeneous or homogeneous groups of QDs which have been purposefully and precisely clustered in order to produce nanophotonic materials with desired electronic and optical properties. The directed clustering of QDs may substantially affect the energy transfer from photonic to electronic energy within a nanophotonic material or environment. As used herein, a nanophotonic environment includes but is not limited to QD-based electronics and computing, solar cells, lighting or display applications, and optically-based biological detection. In one embodiment, the QD clusters as described herein comprise more than one colloidal semiconductor nanocrystal QD. In one such embodiment, a QD cluster may include a range of approximately 2-20 QDs. In a particular embodiment, a QD cluster as described herein comprises approximately 2, 3, 4, 5, 6, 7, 8, 9, 10, 11, 12, 13, 14, 15, 16, 17, 18, 19, and 20 selected QDs. In another particular embodiment, a QD cluster as described herein comprises a specific number of QDs, or a QD multimer, such as at least one of a QD dimer, QD trimer, QD tetramer, QD pentamer, QD hexamer, and QD heptamer.

A QD cluster as described herein may be a heterodimer composed of a mixture of QDs. In one embodiment, a heterodimer QD cluster may comprise one each of a type-I band alignment QD and a type-II band alignment QD. In another embodiment, a heterodimer QD cluster may comprise one each of a type-I band alignment QD and a UCQD. In yet another embodiment, a heterodimer QD cluster may comprise one each of a type-II band alignment QD and a UCQD. In still another embodiment, a heterodimer QD cluster may comprise at least one of a type-I and type-II band alignment QD and a UCQD. In particular embodiments, a QD cluster as described herein may be a heterodimer comprised of a mixture of core only QDs with one or more core-shell QDs having type-I band alignment or core-shell QDs having type-II, or UCQDs.

In one embodiment, each QD within a QD cluster may be a different size from the other QDs. In another embodiment, a QDs of different sized may be selected according to the disclosure herein. In yet another embodiment, QD clusters of different sizes may be selected according to the disclosure herein. In a certain embodiments, the size of a QD heterodimer may have an aerodynamic size that is different from the aerodynamic size of a homodimer, homotrimer or other cluster of QDs of a first size and an aerodynamic size that is distinct from a of the homodimer, homotrimer, or other cluster of QDs of a second size. In a preferred embodiment, the overlap between the size of the heterodimer and other peaks in the size distribution is less than 60%, 50%, 40%, 30%, 20%, 10% or 5%.

In another embodiment, a QD cluster as described herein may be a homodimer comprising a pair of identical or similar QDs. In one such embodiment, a homodimer QD cluster may comprise a pair of core only QDs. In a particular embodiment, a homodimer QD cluster may comprise a pair of core-shell QDs having type-I band alignment. A certain embodiment of a homodimer QD cluster may comprise a pair of core-shell QDs having type-II band alignment. Another certain embodiment may comprise a homodimer QD cluster including a pair of UCQDs. In still another alternative embodiment, a QD cluster may contain one or more metallic, oxide or organic particles, wherein there is one or more of these and a QD—in all its variations.

In one embodiment, the QD clusters as described herein may be tuned to comprise desired physical properties such as absorption, emission, and excitonic lifetime over a broad range so that the QD clusters can be applied to improve energy storage, photovoltaic devices, solar cells, lasing, biomedical markers, and catalysis. In one such embodiment, the QD clusters disclosed herein may comprise QDs that are clustered in a particular number and in controlled geometries thereby tuning the physical, optical, photonic and electronic properties of the QD cluster (such as absorption and emission intensity, composite wavelength, and lifetime). In particular embodiments, a QD cluster may include a desired number and geometry of one or more core only semiconducting QDs, core-shell QDs having type-I band alignment, core-shell QDs having type-II band alignment, and UCQDs, or combinations thereof.

As used herein, type-II QDs have a staggered band gap such that either the electron or the hole resides within the shell, in contrast to type-I QDs where both electron and hole likely remain within the core. The increased separation of the electron-hole pair in type II QDs leads to longer lifetimes and increasing the time scale of electron-hole recombination allows for increased migration of charge carriers to electrodes. The increased migration leads to further increases in the current and power harvested by photovoltaic cells.

As used herein, UCQDs, (upconverting nanoparticles) capture photons in the NIR range and, with double excitation, increase the emitted photon's energy into the visible region of the spectrum where other nanoparticles absorb efficiently. In certain embodiments of QD clusters described herein, clustering UCQDs with other types of QDs can affect how composite clusters internally transfer energy both in terms of efficiency and timescale, and provide a novel route for energy harvest in photovoltaic devices. For example, by clustering multiple QDs, rainbow solar cells can be composed with the relative absorption at each wavelength or band of wavelengths being tuned by cluster composition in dimension, composition and number.

In certain embodiments, the photonic properties of heterogeneously clustered QDs may depend on the structure of each constituent particle and their alignment in assembly (e.g. inter-particle distances and orientations, if the QDs are anisotropic and exhibit polarized emission properties). For example, the relative orientation of QDs may control the energy levels, electron transport within the clusters, and absorption and emission profiles in both time and space. Similarly, in alternative embodiments, clustering otherwise identical QDs may also affect their emission lifetime, emission spectrum, and relative quantum efficiency.

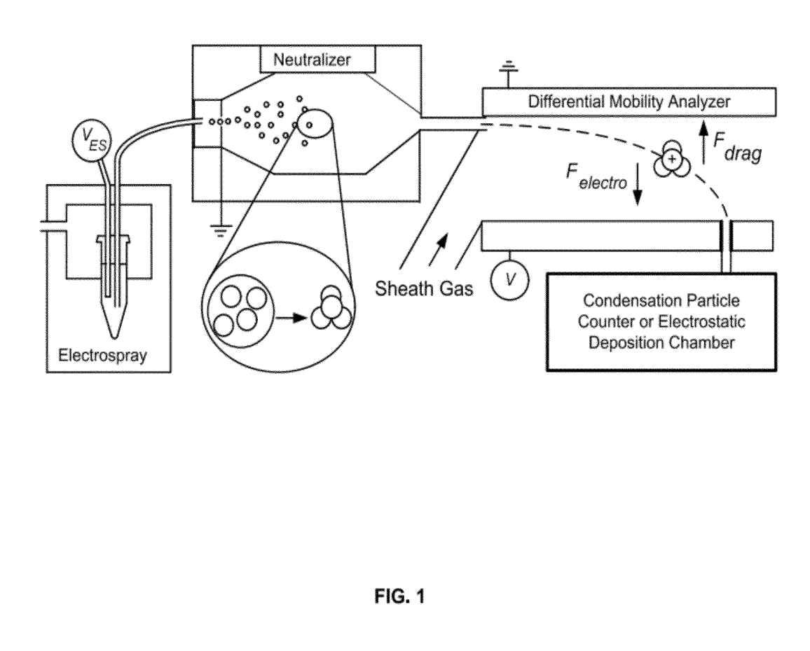

Methods of producing QD clusters are also described herein. In one embodiment, QD clusters are generated using the reliable electrospray droplet induced clustering and purification (REDICAP) technique. The REDICAP technique exploits the ability of aerosolized droplets to encapsulate QDs. In particular embodiments of the methods disclosed herein, the REDICAP technique traps multiple and well-dispersed QDs (typically 2 to 50 nm in size including shell and organic coating) within an electrospray droplet (120 to 350 nm in diameter) entrained in a stream of nitrogen at atmospheric pressure. In one such embodiment, as the droplet evaporates (see, e.g., FIG. 1), capillary forces drive the QDs to cluster, overcoming solution phase electrostatic repulsion. In particular embodiments, the QDs within a QD clusters may be held together by van der Waal's forces and also in some cases intermolecular entanglement between surface coatings. In certain embodiments, the droplets may be formed by electrospray, nebulization, atomization, and other droplet generating techniques known to those skilled in the art. In certain embodiments of the methods of making precision QD clusters described herein, the average number of QDs per cluster may be tuned by balancing the bulk concentration of the QDs against the average volume of the electrospray droplet.

In embodiments of the methods of making precision QD clusters disclosed herein, the REDICAP technique may comprise separating one or more QD clusters of a selected size. In one embodiment, the charge on the cluster is reset using a unipolar or bipolar charge neutralizer. In one such embodiment, the charged, aerosolized QD clusters produced by the electrospray are conveyed into a differential mobility analyzer (DMA) that acts like a band-pass filter. In the DMA the QD clusters of one or more particular selected aerodynamic size (which corresponds to a specific number of particles per QD cluster) are selected. In one embodiment, the composition selected or size selected clusters pass into a condensation particle counter (CPC) for single particle counting. Stepping or scanning across a range of aerodynamic or mobility sizes while counting produces a size distribution. In one embodiment, the peaks in the distribution correspond to particular compositions. The DMA voltage and flow rates used to select particular clusters are informed by the size distribution.

In another embodiment of making precision QD clusters, a preferred size or composition of selected QD clusters are channeled into an electrostatic deposition (ED) chamber. In the ED chamber, the QD clusters deposit electrostatically (the cluster acquired a charge within the electrospray) or electrophoretically onto a desired substrate. In particular embodiments, the QD clusters produced by the methods disclosed herein may be deposited electrostatically onto a substrate for confirmation and analysis, such as either transmission electron microscopy (TEM) grids, which can be analyzed to confirm the number of particles per cluster and type of particles composing the cluster, or onto glass rounds for further analysis. In another embodiment, the QD clusters are deposited on substrates thermophoretically for further analysis of their composition.

In one embodiment, the methods of making precision QD clusters described herein may be used to generate QD clusters of a variety of sizes and compositions, including a desired QD cluster yield and selectivity. In one such embodiment, the QD cluster selectivity or purity is defined as the fraction of the QD clusters exiting the DMA or deposited electrostatically that are of the desired size, geometry, and composition (i.e. what fraction of the expected QD cluster dimers are actually dimers, as opposed to monomers or trimers, etc). In particular embodiments, the QD clusters produced according to the methods disclosed herein have a purity of approximately ranging from 40% to 99%. In another embodiment, the QD clusters produced according to the methods disclosed herein have a purity of approximately greater than 40%, 50%, 60%, 70%, 80%, or 90%. In still another embodiment, the QD clusters produced according to the methods disclosed herein have a purity of approximately greater than 90%. In one such embodiment, the QD clusters produced have a purity of approximately 90%, 91%, 92%, 93%, 94%, 95%, 96%, 97%, 98%, and 99%.

In one embodiment of the methods of making precision QD clusters described herein, one or more factors may influence the yield and/or selectivity of a particular QD cluster produced by the REDICAP technique. In one such embodiment, the mean electrospray droplet diameter may influence the yield and/or selectivity of a particular QD cluster. In certain such embodiments, the electrospray droplet diameter ranges in size from approximately 3 nm to 40 microns during the REDICAP process. In more particular embodiment, the electrospray droplet diameter may be approximately 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 35 nm, 40 nm, 45 nm, 50 nm, 75 nm, 100 nm, 150 nm, 200 nm, 250 nm, 300 nm, 350 nm, 400 nm, 450 nm, 500 nm, 550 nm, 600 nm, 650 nm, 700 nm, 750 nm, 800 nm, 850 nm, 900 nm, 1 micron, 5 microns, 10 microns, 15 microns, 20 microns, 25 microns, 30 microns, 35 microns, to 40 microns during the REDICAP process.

In another embodiment, the nanoparticle concentration during the REDICAP process may influence the yield and/or selectivity of a particular QD cluster. For example, the nanoparticle concentration during the REDICAP process may range from liquid concentrations of approximately 3×10⁷ particles/mL to approximately 2×10¹⁸ particles/mL. In particular embodiments, the nanoparticle concentration during the REDICAP process may be approximately 3×10⁷ particles/mL, 5×10⁷ particles/mL, 7×10⁷ particles/mL, 9×10⁷ particles/mL, 1×10⁸ particles/mL, 1×10⁹ particles/mL, 1×10¹⁰ particles/mL, 1×10¹¹ particles/mL, 1×10¹² particles/mL, 1×10¹³ particles/mL, 1×10¹⁴ particles/mL, 1×10¹⁵ particles/mL, 1×10¹⁶ particles/mL, 1×10¹⁷ particles/mL, 1×10¹⁸ particles/mL, and 2×10¹⁸ particles/mL. In one such particular embodiment, the naonparticle concentration for the production of QD dimers may be approximately between 6×10¹⁴ particles/mL and 1.1×10¹⁵ particles/mL for a 150 nm droplet. In another such particular embodiment, the nanoparticle concentration for the production of QD trimers may be approximately between 1.2×10¹⁵ particles/mL and 2.2×10¹⁵ particles/mL for an approximately 150 nm droplet. It will be understood from the specifications and examples disclosed herein by those skilled in the art that the optimum concentration may increase with smaller droplet diameters and correspondingly decrease with larger droplet diameters. In one such particular embodiment, the nanoparticle concentration for the production of QD dimers may be approximately between 2.5×10¹⁴ particles/mL and 4.7×10¹⁴ particles/mL for an approximately 200 nm droplet. In another such particular embodiment, the nanoparticle concentration for the production of QD trimers may be approximately between 4.8×10¹⁴ particles/mL and 9.3×10¹⁴ particles/mL for an approximately 200 nm droplet. In one such particular embodiment, the nanoparticle concentration for the production of QD dimers may be approximately between 1.3×10¹⁴ particles/mL and 2.4×10¹⁴ particles/mL for a 250 nm droplet. In another such particular embodiment, the nanoparticle concentration for the production of QD trimers may be approximately between 2.5×10¹⁴ particles/mL and 4.8×10¹⁴ particles/mL for a 250 nm droplet. The overlap between the ranges formed a key barrier to the implementation of this art that is resolved herein by tuning both the particle concentration and droplet diameter simultaneously.]

In another embodiment, a salt concentration in the electrospray solution for use during the REDICAP process may be minimized or eliminated before use. Salts in the electrospray solution such as, for example, sodium chloride, sodium borate, sodium citrate, etc., may precipitate onto the surface of colloidal QDs or QD clusters as the aerosolized droplet evaporates, leaving a salt layer. Accordingly, significant amounts of salts in the electrospray solution can lead to an undesirable increase in the apparent size of the QD clusters. This in turn may lead to overlap between and obscuration of neighboring peaks in the size distribution which can make distinction between clusters using the DMA difficult. In one embodiment, the salts are removed from the electrospray solution containing the QDs before aerosolization.

In one embodiment of the methods of making QD clusters disclosed herein, QDs produced in the aerosol phase may be concentrated above a coagulation concentration or allowed to interact for longer than a coagulation time scale to induce aggregation. (The coagulation time scale and coagulation concentration are interdependent.) In an alternative embodiment, colloidal QDs entrained in dry gas flow may be concentrated above the coagulation concentration or allowed to interact for longer than the coagulation time scale to induce aggregation. Concentrating may be performed by aerodynamic lensing, electrostatic concentration or thermophoretic techniques.

In another embodiment of the methods of making QD clusters disclosed herein, colloidal QDs are induced to aggregate in solution by changing the pH of the solution across the particle's isoelectric point (pI), increasing the ionic strength of the solution to decrease the electrostatic screening length, or by performing, at least partial, ligand exchange. The QD aggregates formed in this way may be held together at least partially by van der Waals forces. In particular embodiments, the QD clusters are entrained in an aerosol flow by use of electrospray, nebulization, atomization, and other droplet forming techniques known to those skilled in the art.

In one embodiment, certain QD clusters disclosed herein may be selected from a distribution of QD aggregates by aerodynamic size or mobility size, which corresponds to QD cluster composition. In one such embodiment, the charge on the QD cluster is reset using a unipolar or bipolar charge neutralizer. The charged, aerosolized QD clusters are conveyed into a DMA. In the DMA QD clusters of particular selected aerodynamic size (which corresponds to a specific number of particles per QD cluster) are selected. The composition selected or size selected QD clusters pass into a CPC for single particle counting. Stepping or scanning across a range of aerodynamic or mobility sizes while counting produces a size distribution. The peaks in the distribution correspond to particular compositions. The DMA voltage and flow rates used to select particular QD clusters are informed by the size distribution. The size or composition selected QD clusters are channeled into an ED chamber where the QD clusters deposit electrostatically or electrophoretically onto a desired substrate. In particular embodiments, the QD clusters produced by the methods disclosed herein may be deposited electrostatically onto a substrate for confirmation and analysis, such as either TEM grids, which can be analyzed to confirm the number of particles per cluster and type of particles composing the cluster, or onto glass rounds for further analysis. In another embodiment, the QD clusters are deposited on substrates thermophoretically for further analysis of their composition.

In one embodiment, colloidal QD clusters can be incorporated within electronic polymers. For example, polymers can be included within electrospray droplet solutions at concentrations such that one or more polymer strands resides within each electrospray droplet. As the electrospray droplet evaporates, QD clusters within electrospray droplet may be encapsulated within the dried polymer. In one such embodiment, at least some portion of the electronic polymer coats the outer surface of the QD cluster. Particular embodiments may comprise varying the stoichometric ratio between the QDs and the polymer strands within the electrospray droplet. In one such particular embodiment, the thickness of the polymer coating on the QD cluster can be tuned and controlled by varying the stoichometric ratio between the QDs and the polymer strands within the electrospray droplet. A variety of small and long chain polymers can be employed including dielectric polymers, redox polymers, conducting polymers, etc. These polymer coatings can protect and preserve the QD cluster from oxidation and photooxidative stresses, tune electron or exciton transport by enhancing or attenuating it, and further tune transport by matching or aligning bandgaps between clusters and other device elements including substrates, etc.

As disclosed herein, the orientation between individual QDs that are clustered within a QD cluster can be controlled and tuned. In one embodiment, the aerodynamic drag force acting on the cluster within the DMA depends on the angle between adjacent pairs of QDs. For example, QDs that are parallel or collinear may have a smaller average aerodynamic size than those that are perpendicular. Intermediate orientations have intermediate effective aerodynamic sizes. Commercially available DMAs have subnanometer resolutions (e.g., TSI, MN and Grimm, GA). More advanced DMAs have sub-angstrom resolution of diameters, making this a powerful tool to distinguish sizes (i.e., U.S. Pat. Nos. 5,869,831 and 5,936,242).

In one embodiment, the QD clusters produced according to the methods disclosed herein retain orientation upon deposition (even after impact with a substrate). In certain embodiments, the orientation separated QDs may be fixed in orientation by sintering the QDs together. For the process of sintering described herein, a tube furnace may be inserted in the flow stream following the DMA. The residence time of the tube furnace and temperature within the tube furnace, along with the melting/sintering point of the QD cluster materials, determines the degree of sintering. Upon cooling after sintering, the QD clusters may become locked with their relative orientations fixed in place. The degree of sintering can be ascertained by TEM and related microscopy techniques or by appending a second DMA with CPC or electrometer to obtain the second size distribution.

In another embodiment, the QD clusters may be sintered together before separation based on QD cluster size. In one such embodiment, sintering may be accomplished by inserting the tube furnace before the DMA. The degree of sintering can be ascertained by shifts of the peaks within the size distribution and confirmed via TEM and related techniques known by those skilled in the art.

In one embodiment of the methods of making QD clusters disclosed herein, selected materials may be included in the evaporating electrospray droplets to form a coating on the surface of the QD clusters. In one such embodiment, materials selected from calcining, glass forming, vitrifying or ceramic forming materials are included in the evaporating electrospray droplets that form the QD clusters. In one such particular embodiment, as the QD clusters form, one or more materials may be included in the evaporating electrospray droplets in order to form a coating of the material on the QD cluster. The coating on the QD clusters may lock the orientation of the QDs within a cluster in place by passing the clusters through a tube furnace before or after separation by size. Exemplary materials for coating the QD clusters may be of modest surface tension and viscosity before evaporation of the electrospray droplet so that the material conforms to the topology of the QD particles. Exemplary materials include but are not limited to tetraethyl orthosilicate (TEOS), tetramethyl orthosilicate (TMOS), etc. In one example, the coating materials may be doped to tune the electron or exciton transport properties using techniques known to those skilled in the art.

In one embodiment, to enhance electron transport of the QD clusters disclosed herein, a porogen may also be included in QD clusters. In another embodiment, the QD clusters disclosed herein may be included within annealed layers of conductive or redox polymers. In still another embodiment, the clusters may be prepared with relatively stiff polymers incorporated in the initial electrospray droplet. In one such embodiment, as the droplets dry, these polymers may form a thin coating that can provide additional resistance to substrate impact forces. In yet another embodiment, the incorporated polymers can be a reactive polymer (i.e. photo reactive) or combination of reactive polymers (i.e. a diluted epoxy). For these, and additional embodiments, the polymers may be incorporated within the electrospray droplets that dry to form the QD cluster, thereby resulting in a thin coating on the QD cluster. The polymer coating may be fixed into place by applying heat (i.e. a tube furnace) or light to the cluster.

In certain other embodiments, the clusters pass through supercritical condensation chambers in which the clusters become immersed in media that does not change the relative orientation. In certain other embodiments, the orientation between individual QDs that are elongated within a quantum dot cluster can be tuned by selective surface coating. In one embodiment, the QDs have Janus coatings wherein one portion of the quantum dot has a thicker coating than the remaining portion of the quantum dot. For example, thicker organic coatings on one end versus the other when coupled with DMA separation may lead to control of the angle by tuning the relative thicknesses of the coating.

In one embodiment of the QD clusters disclosed herein, the distance between adjacent QDs may control the photonic, optical, physical and electronic properties of the QD clusters. In one such embodiment, an organic coating on an individual QD may be used to govern the distance between adjacent QDs in a QD cluster. In certain embodiments, the QD clusters may be heated to desorb the organic coatings and thereby decrease the distance between QDs. In certain embodiments, the QD clusters may be heated to remove the organic coatings or by burning them.

In one embodiment, the QD clusters may be heated until the QDs begin to sinter together. For example, the QD clusters may be passed through an aerosol tube furnace, wherein the residence time and temperature control the heat transfer and the corresponding degree of desorption, burning, or sintering. In particular embodiments, the QD cluster is partially sintered. In other embodiments, the QD cluster is nearly completely sintered. In alternative embodiments, the heating is performed before size or composition separation with one or more DMAs. In still other embodiments, the heating is performed after size or composition based separation. In each of these embodiments, the distance between QDs within one or more clusters can be precisely tuned to affect the optical, photonic, physical and electronic properties of the cluster.

The QD clusters disclosed herein can be chemically modified after QD cluster formation. For example, in certain embodiments, the aerosol stream is bubbled through a liquid solution containing organic moieties, proteins, surfactants, nucleic acids, self assembling monolayers, or/and other cross linkers. These molecules can lock in and stabilize the QD clusters and prevent aggregation of clusters. In certain embodiments, these stabilized QD clusters are used to form devices using traditional liquid methods. In certain other embodiments, these molecules are added in the gas phase by collision near the coagulation limit before resuspension or deposition and coat the clusters to provide unique properties or prevent inadvertent aggregation in solution.

In certain embodiments, the methods of producing QD clusters as disclosed herein include one or more advantages over traditional chemical and biological techniques used for QD cluster production. For example, the advantages of preparing QD clusters using the REDICAP technique and other cluster preparation methods described herein include: (1) This is a self-assembly technique that allows cluster composition to be physically tuned without relying on complicated reaction schemes or biological moieties. (2) It is simple enough to be relatively inexpensive, highly reproducible, and fast. (3) The technique uses aqueous solutions so that QDs can be prepared directly from solutions provided by commercial suppliers. (4) The instrumentation operates at atmospheric pressures, eliminating the need for costly and complicated auxiliary equipment, including turbo pumps. (5) The stability of the QD cluster does not depend on chemical, thermal or light sensitive linkers. This provides new opportunities to decorate the external surface of nanoparticles. (6) Dielectric coatings can be added in solution or removed by thermal desorption in the aerosol phase to tune the emission and stability of QD clusters. (7) It can be scaled up to commercial grade intensity with processes that are assembled out of commercially available components. (8) The disclosed QD clusters and method to make them are amenable to high throughput processing through roll-to-roll processing, either by the direct aerosol technique or after rehydration by slot coating, screen printing, ink jet printing, air-brush spray, ultrasonic spray and other techniques known in the art. (8) They can be readily applied to flexible and curved substrates for flexible solar cells including fabrics.

Industrially or commercially interesting QDs or clusters containing QDs may be incorporated within devices or device elements. In certain embodiments, this can be accomplished by depositing the QD clusters using electrostatic, electrophoretic, or thermophoretic means. In one such embodiment, this may result in a broad, generally random spatial distribution of specific QD clusters (by composition or size) on the substrate.

Techniques are known in the art to control the deposition of the QD clusters disclosed herein onto substrates. In one embodiment, the QD clusters may be deposited onto a patterned substrate. In one such embodiment, the substrates may be patterned with space charge. In another embodiment, the deposition of QD clusters can be guided by topologically patterned, electrostatically addressed, or laser patterned substrates. In yet another embodiment, the clusters are guided into specific orientation and/or specific positions by surface forces induced by curvature at air-water or air-liquid interfaces. Examples of the substrate materials disclosed herein may include metallic electrodes, ITO electrodes, electrodes formed out of transparent carbon nanotubes embedded as a composite, etc.

In one embodiment, the QD clusters may be returned to liquid by bubbling the gas stream through a liquid, electrostatic deposition into liquid filled Petri dishes or other open liquid filled containers, etc. In another embodiment, a layer containing QDs can be formed on the surface of a device by traditional means such as spin coating at. In a further embodiment, the QD clusters can be located in rehydrated or nucleated droplets of hydrophilic or hydrophobic liquids and then deposited onto flexible substrate for rapid manufacture. In certain embodiments, individual QD clusters may preferably be separated from the next QD cluster to minimize “cross talk” between QD clusters. For example, the degree of cross talk can be moderated by coating the clusters with techniques and embodiments as disclosed herein.

In additional embodiments, the QD clusters disclosed herein can be incorporated within or between one or more specific layers of a device. In one such embodiment, a substrate of a device may be coated with one or more intervening materials such as a polymeric layer. For example, the polymer can be a photoresist, an electrically conductive polymer, an electrically insulating polymer, a redox polymer, etc. The QD clusters may then be deposited on the coated substrate electrostatically, electrophoretically, or possibly thermophoretically. One or more additional layers of a device located above a first QD cluster layer can be formed by depositing an additional layer of intervening material, such as a polymer. Polymer layers can be added by spin coating, CVD, atomic layer deposition, etc. A second QD cluster layer may be formed by performing a second QD cluster deposition. In certain embodiments, the QD clusters in the second layer may or may not be identical in size or composition to those in the first. The process may be repeated as need to build up the desired number of layers of substrate and QD clusters to complete the device or device element. In a further embodiment, QD cluster containing layers can be positioned, addressed, and interconnected using traditional photolithography techniques.

The QD clusters as disclosed herein may also be oriented and aligned as desired when they are deposited electrostatically on a substrate. In one embodiment, the QD clusters may be deposited electrostatically on a substrate that has been topographically patterned using techniques such as, for example, e-beam lithography or nanolithography. In one such embodiment, substrates may be patterned with protrusions or ridges, wherein the protrusions or ridges may have a pitch ranging from approximately 10 nm to 50 nm wide. In particular embodiments, one or more QDs may align with this lithography patterning. In another embodiment, aligning pairs of QD clusters, such as dimers and trimers, using patterning methods as described herein can allow for the control of the polarized excitation of the QD clusters. In yet another embodiment, orienting and aligning QD clusters allows for independent control of the lifetime, intensity and spectrum of the polarization.

In another embodiment of the methods of making the QD clusters as disclosed herein, one or more QD clusters may be oriented vertically or horizontally on a substrate by patterning the substrate with trapezoids or v-shaped crevices. For example, in particular embodiments of the methods disclosed herein, the patterning of the substrate may involve an ebeam lithography followed by a KOH etch to create a v-shaped topography. In one such embodiment, the patterning of the substrate can modulate the angle of the nonisotropic QD clusters with respect to the substrate surface, providing opportunity to control the excitation and emission of these clusters for device purposes. In a further embodiment, protrusions on a substrate patterned in relief can be used to orient and guide elongated QD clusters into specific locations on a substrate surface. For example, elongated QDs tend to align with the gradient in liquid interfacial height.

In one embodiment, the QD clusters disclosed herein may be used as a sensing element or assay for ex vivo biological, biochemical or bioterrorism purposes. In another embodiment, the QD clusters disclosed herein may be used as an in vivo probe or target. In one such embodiment, the QD clusters disclosed herein may be used in a sandwich assay wherein a substrate may be coated, for example, with a metallic layer or layer of metallic nanoparticles (e.g. gold or silver). A receptor molecule, antibody, or recognition molecule may then be coated on this substrate. A sample comprising test molecules, such as, for example, DNA, peptides, and antigens may be introduced onto the substrate, along with QD clusters surface modified to recognize the test molecule. In a preferred embodiment of the sensing element or assay disclosed herein, QD clusters composed of QDs with, for example, type I and/or type II band alignment in any QD combination with a slow and fast lifetime may be used. Without target molecule recognition in the assay, stimulating the slow responding QD provides background free detection at the wavelength of the faster QD with suitable energy transport. With target molecule recognition in the assay, the signal decreases because of metal QD signal attenuation at the recombination site.

Nanophotonic devices and environments are also disclosed herein comprising one or more QD clusters. In certain embodiments, nanophotonic devices are selected from at least one of photovoltaic cells, solar cells, quantum computers, biological sensors, biomolecular sensing chips, QD electronics, QD computers, lighting, displays, and other nanomaterials. In yet another embodiment, a QD cluster as disclosed herein may be used to improve QD-based electronics including light emitting diodes (QD-LEDs); white light emitting diodes (QD-WLEDs); QD diode lasers; QD-transistors. In still another embodiment, a QD cluster as disclosed herein may be used to provide a new and perhaps less expensive route to tune the absorption and emission of solar energy harvesting and lighting applications.

Each of the references cited in this disclosure, including the references cited in the Examples, are incorporated herein in their entirety by reference. Additionally, the Appendix filed herewith is considered part of this application and the contents thereof are incorporated herein by reference.

### EXAMPLES

### Example 1

### Materials and Methods

The attributes of the electrospray droplets produced during the REDICAP technique were investigated as governing the yield and selectivity of QD cluster production. Sugar solutions in ammonium acetate were used to evaluate the size of the electrospray droplets. When electrosprayed from a cone shaped meniscus, the ammonium acetate and water evaporate leaving a sugar nanoparticle with a diameter that is proportional to the diameter of the initial droplet. A solution of 4.85% (v/v) sucrose was prepared by adding 0.77 g of sucrose into a 15 mL polycarbonate tube and raising the liquid level to 10.0 mL with deionized water. Three microliters of this solution was added to 997 mL of 2.0 to 20 mmol/L ammonium acetate. Conservation of sugar mass between the droplet and the sugar particle (and equivalence of density in the electrosprayed solution with that in the droplet) finds

$${d}_{drop} = \sqrt[3]{\frac{{ρ}_{sugar} {V}_{total}}{{m}_{sugar}^{total}}} {d}_{np} , \qquad ( 1 )$$

where ρ_{sugar} (=1.587 g/mL) is the density of dry table sugar, mₜₒₜₐₗ is the total mass of sugar used to make the solution, and Vₜₒₜₐₗ (=10*1000/3 mL) is the total equivalent volume of liquid including dilution factors. For the conditions here, the coefficient is a constant multiple of 19.01.

The samples were electrosprayed using an Electrospray Aerosol Generator (TSI Inc., Shoreview, Minn., #3480) through a nominally 25 μm inner diameter capillary with a tapered outlet. The stable cone-jet condition was confirmed by monitoring both the current and visual appearance of the meniscus at the capillary tip. Electrospray sheath gas flow rates were approximately 0.2 L/min of CO₂ and 1.0 L/min of air. Droplets containing the polymer were stabilized by passage through a charge neutralizer, in which a Po-210 source reduced the charge on the droplet using a modified Boltzmann distribution.

The QD size distribution was then measured using a DMA coupled to a CPC (Pease et al., Quantifying the Surface Coverage of Conjugate Molecules on Functionalized Nanoparticles, Journal of Physical Chemistry. C 111 (2007) 17155-17157). The DMA acts like a band-pass filter that for a given electrode voltage and gas flow rate enables a narrow size band of ions to be purified and exit for further analysis (Pease et al., Determination of Protein Aggregation with Differential Mobility Analysis: Application to IgG Antibodies, Biotechnology and Bioengineering. 101 (2008) 1214-1222); Pease et al., Length Distributions of Single Wall Carbon Nanotubes in Aqueous Suspensions Measured by Electrospray-Differential Mobility Analysis. Small; 5 (2009) 2894-2901; and Pease et al. 2007). The DMA was operated with sheath gas flow rates of 30 L/min of nitrogen gas in an annular analysis chamber (TSI Inc., #3080). Electrostatic potentials as strong as −10 kV deflected positively charged particles toward collection slits at the distal end of the chamber. Because a negative bias was applied to aerosolized ions within the DMA, only nanoparticles that acquire a positive charge are detected. The monodispersed flow exiting the analysis chamber was directed to a condensation particle counter (CPC). The CPC (TSI Inc., #3776) was operated at 1.5 L/min, so the 1.0 L/min flow exiting the DMA was supplemented with 0.5 L/min of ambient air filtered through a HEPA filter. Within the CPC, particles passed through a saturated butanol environment and grew into droplets several microns in size, which were counted individually as they obscure light impinging on a photodetector. The CPC reported the number of particles passing the detector per unit time, after averaging for 20 s to minimize any transient responses. By varying the voltage in the DMA, nanoparticles ranging in diameter from 3 nm to 30 nm, in 0.2 nm increments, were measured. Alternatively, the monodispersed flow exiting the DMA were directed to the ED chamber where particles in a 1.5 L/min flow were deposited using electrostatic potentials as high as −10 kV for further analysis by TEM. The ES-DMA-CPC system is sometimes referred to as gas-phase electrophoretic mobility molecular analysis (GEMMA).

Conversion to size was performed assuming the particles to be spheres with a Cunningham slip correction factor of C_{c}=1+Kn(α+βexp(γ/Kn)), where Kn=2γ/d, d is the particle's diameter, α=1.257, β=0.40, γ=1.110, and the gas mean free path at room temperature is λ=66 nm. The conversion from voltage to mobility size has been described in detail elsewhere (Pease et al. 2007). Because the fraction of particles emerging with a positive charge is size dependent, a modified expression for the Boltzmann distribution was used to transform the distribution of positively charged particles into the complete distribution of all particles regardless of charge (Pease et al. 2007).

To demonstrate the clustering of nanoparticles, 605 ITK™ carboxyl QDs were obtained from Invitrogen (Carlsbad, Calif.). The QDs comprised a CdSe core with a ZnS shell and covered with a thin organic layer terminating in a carboxylic acid moiety. The QDs were delivered at a concentration of 8 μM and diluted by 20×-100× in 2-20 mM ammonium acetate until they reach the concentration reported in the captions. Invitrogen reported that their QDs are rod-like in shape with an aspect ratio of approximately 2-3. These QDs were received in a solvent containing borate and other proprietary components that will coat the external surface of the quantum dot as the droplet evaporates.

In this example, the scaling analysis of Pease, et al. was extended, to predict the concentration at which QD clusters will form (Pease et al. 2008). A Monte Carlo simulation and the post processing of the data were then described to estimate how the yield and selectivity depend on distributions in droplet and nanoparticle density and size.

Previous efforts to understand QD aggregation have established formulas based on scaling considerations to determine the cut off concentration. However, those efforts did not consider the concentrations at which QD dimers and trimers would be optimized. Each of these concentrations may depend on the nanoparticle concentration, the spatial distribution of nanoparticles, the distribution of nanoparticle droplets, the spatial distribution of droplets, and the distribution of droplet diameters. Each of these parameters was examined here beginning by modifying the scaling relation to provide a straightforward form with which to summarize the results of the simulations. Adjustments include allowing for multiple particles per droplet by including the number of particles, n, as a parameter for purposes of controlling the formation of clusters containing more than a single particle. Modifications also included the scaling relation to account for these other parameters by including a leading coefficient α,

$${N}_{co} = \frac{1}{α} \frac{6 n}{π {d}_{drop}^{3}} . \qquad ( 2 )$$

The results of a Monte Carlo simulation were used to establish a numerical value for α. This expression with units of number of particles per volume can be converted to molar or mass per volume units with M_{co}=6nM_{w}*(απd_{drop}³N_{A}) and C_{co}=6n/(απd_{drop}³N_{A}), where M_{w} is the molecular weight of the particle, N_{A} is Avogadro's number.

The Monte Carlo simulation incorporates and accounts for spatial and size distributions of the droplets and nanoparticles. Code for the simulations was developed using Visual Basic for Applications (VBA). The electrospray droplet diameter distribution was assumed to be Gaussian in the absence of a general model predicting electrospray droplet size distributions from first principles (most models are limited to scaling arguments or represent empirical fits for particular electrospray systems). A log-normal distribution was not used for the droplets because the size distributions for sugar particles are best fit using Gaussian distributions; and no indication of log-normal statistics. However, it was noted that some of the nanoparticle distributions appear to follow Poisson statistics. The Gaussian distribution is given as

f(x,A_{drop},μ_{drop},σ_{drop})=A_{drop}Exp[−(x−μ_{drop})²/(2σ_{drop}²)] (3)

where the maximum, mean, and standard deviation are A_{drop}, μ_{drop}, and σ_{drop}, respectively. The droplet size distribution for the simulation was obtained by selecting a pair of random numbers, (x, y), where x∈[0, 3μ_{drop}] and y∈[0, A_{drop}]. This domain limits σ_{drop}/μ_{drop}<½ to prevent generating droplets with negative diameters. If the pair falls within an envelope defined by Eq. 3 (i.e. y<f), then x is assumed to be a diameter of the droplet and used in the calculation. Otherwise, a new (x,y) is selected until the condition is satisfied. The nanoparticle diameter is also drawn from a Gaussian distribution,

f(x,Aₙₚ,μₙₚ,σₙₚ)=AₙₚExp└−(x−μₙₚ)²/(2σₙₚ²)┘ (4)

where Aₙₚ, μₙₚ, and σₙₚ are the maximum, mean, and standard deviation, respectively. A pair of random numbers, (x, y), is selected, where x∈[0, 3μₙₚ] and y∈[0, Aₙₚ], and if the pair falls within the envelop defined by Eq. (4), then x is assumed to be a diameter of the nanoparticle. The domain was confined to three times the mean as a more liberal assumption is equivalent to allowing diameters to be negative. The Gaussian expression is satisfactory for many nanoparticle systems including commercially synthesized QDs, gold nanoparticles, proteins, and viruses (Pease et al. 2008; Pease et al. 2009; Pease et al. 2007). The centers of the nanoparticles and the droplets are randomly distributed by using the rnd function in VBA for each of the three linear dimensions within a cubic box. The nanoparticle diameter is assumed to be much smaller than the droplet diameter and the droplet diameter to be much smaller than the domain from which the droplet coordinates were selected.

The simulation occurs within a cubic box spanning 1742.8 nm along each edge. This length was chosen to allow the coordinates to be observed in an MS Excel 2003 spreadsheet for error checking purposes, keeping the number of required rows within the maximum allowed by MS Excel (˜6.5×10⁶) when the nanoparticle number density reaches 1.0·10¹⁶ particles/mL. The simulation assumes the cubic boxes to be stacked periodically. If the boundary of the box transects a droplet, the protruding portion of that droplet samples from an identical neighboring box to eliminate edge effects. This strategy prevents under counting that could occur if (i) there were no particles that were present outside of the box and (ii) the droplet protruded outside of the box. The simulation does not control for spatial overlap of the randomly selected particle coordinates nor does it include the attractive role of van der Waals forces that can drive particles together within the solution.

The program operates as follows. First, the code populates the three dimensional locations and diameters of the nanoparticles, followed by the three dimension locations and diameters of the electrospray droplets, storing them within arrays to accelerate computation. For each droplet, the code determines whether each individual nanoparticle lies within the droplet. If the Euclidian distance between the centers of the droplet and a nanoparticle is less than or equal to the droplet radius then the nanoparticle satisfies the criterion for residing within the droplet. The total number of nanoparticles meeting the criterion becomes the number of particles within a cluster, which is then reported and normalized by the total number of nanoparticles to provide the fractional yield of each type of cluster. The number of empty droplets was also tabulated but not reported here.

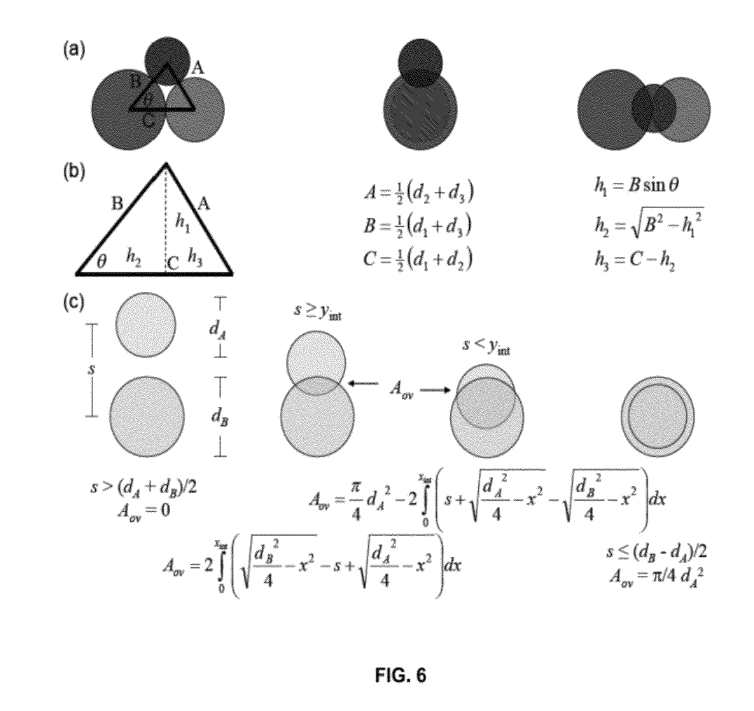

To determine the size distribution, the mobility diameter, dₘ, of the nanoparticle cluster was calculated. The mobility diameter is the aerodynamic size determined using the DMA. There are two options for determining the mobility diameter. The first option as outlined in Pease, et al. is to calculate the three projected areas, Aᵢ, orthogonal to the cluster's principle axes (see FIG. 6a) (Pease et al. 2007). The projected areas are combined into the mobility diameter with

$${d}_{m} = {( \frac{\sqrt{π}}{6} {\sum }_{i = 1}^{3} \frac{1}{\sqrt{{A}_{i}}} )}^{- 1} . \qquad ( 5 )$$

These projected areas are estimated by first determining the center-to-center distances, hᵢ, between the circles in each projection. FIG. 6b shows how to determine hᵢ using the law of cosines from the diameters of three particles composing a trimer, for example. The projected areas can then be determined using

Aᵢ=π/4(d₁²+d₂²+d₃²)

A₂=π/4(d₁²+d₃²)−Aₒᵥ(h₁)

A₃=A₁−Aₒᵥ(h₂)−Aₒᵥ(h₃), (6)

where d₁≧d₂≧d₃. The overlap area, Aₒᵥ, is a function of the center-to-center distance and corresponding diameters, and FIG. 6c shows the four expressions used to calculate the overlap depending on s, where

$${x}_{int} = \sqrt{\frac{{d}_{B}^{2}}{4} - {( \frac{{s}^{2} - \frac{1}{4} {d}_{A}^{2} + \frac{1}{4} {d}_{B}^{2}}{2 s} )}^{2} } and {y}_{int} = \frac{{s}^{2} - \frac{1}{4} {d}_{A}^{2} + \frac{1}{4} {d}_{B}^{2}}{2 s} . \qquad ( 7 )$$

The degree of overlap is determined by s, which is approximated by hᵢ for a particular case. A VBA function was constructed in which the rectangle method was used to integrate Aₒᵥ using at least 100 rectangles to reduce the uncertainty to less than 1%.

The second option to determine the mobility diameter of a particle is to employ the proportionality constants determined previously by Pease, et al., for clusters composed of identically sized particles (Leonard F. Pease III, De-Hao Tsai, Rebecca A. Zangmeister, Joshua L. Hertz, Michael R. Zachariah, Michael J. Tarlov, Packing and Size Determination of Colloidal Nanoclusters, Langmuir 26 (2010) 11384-11390.). They show that dₘ=k·d, where d is the diameter of an individual particle in the cluster. The proportionality constant, k, is 1.526, 1.724, and 1.875 for close packed trimers, tetramers, and pentamers, respectively. To use this method for the heterogeneously sized particles contemplated here, d was replaced with

$${d}_{ave} = \frac{{\sum }_{i = 1}^{N} {d}_{i}}{N} . \qquad ( 8 )$$

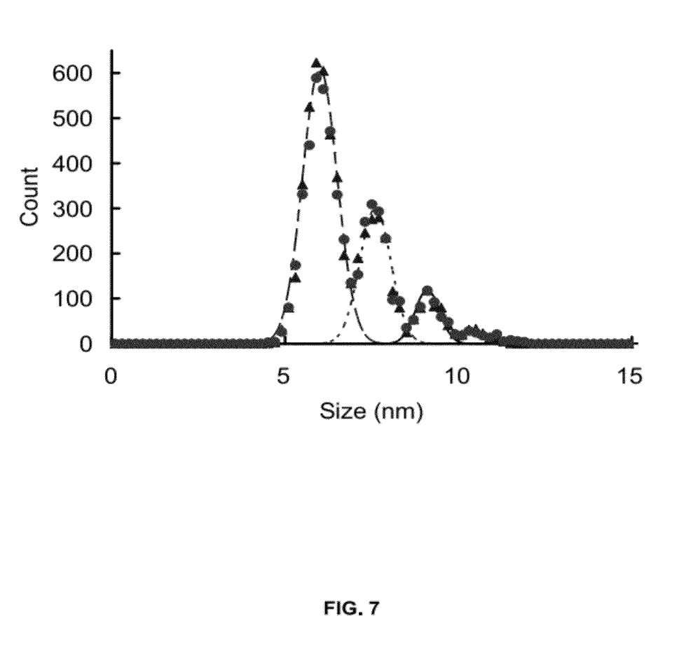

When d₁=d₂=d₃, both methods return identically the same mobility diameter. However, even when the individual diameters are not equal, FIG. 7 shows that the resulting size distributions are remarkably similar. Therefore, the latter option was used to determine the mobility size of higher-order clusters.

A histogram of the mobility diameters of the clusters was prepared by summing the total number of nanoparticles having diameters within 0.2 nm intervals (corresponding to the intervals collected using our ES-DMA-CPC system). The number of particles within each bin is reported versus the center of that interval. For example, the total number of particles residing in a bin from 0.4 to 0.6 nm is reported versus 0.5 nm. Each type of cluster from monomers through hexamers is binned separately and then summed over all clusters to obtain the entire size distribution.

To quantify the selectivity or purity, each component (i.e. type of cluster) of the size distribution was fit with a Gaussian distribution using a best fit (i.e. least squares) approach using expressions similar to Eqs. 3 and 4 as shown in FIG. 7. These fits are then used to determine the overlap between neighboring distributions as metrics of cluster purity after electrostatic deposition. The metric for the impurity of nanoparticle cluster type j is

$${p}_{j} ( {x}_{j}^{max} ) = \frac{f ( {x}_{j}^{max} , {A}_{i} , {μ}_{i} , {σ}_{i} ) + f ( {x}_{j}^{max} , {A}_{k} , {μ}_{k} , {σ}_{k} )}{f ( {x}_{j}^{max} , {A}_{i} , {μ}_{i} , {σ}_{i} ) + {A}_{j} + f ( {x}_{j}^{max} , {A}_{k} , {μ}_{k} , {σ}_{k} )} , \qquad ( 9 )$$

where j=i+1=k−1 and xⱼ^{max} is the maximum of the Gaussian distribution for cluster type j. For example, p₂(x₂^{max}) would determine the fraction of the dimer distribution that was in reality dimers at its peak. This metric increases from zero, where there is no overlap by neighboring distributions, toward unity.

To determine α in Eq. 2, the results of simulations for the fractional yield of monomers were fit with

f(x)=[Exp((N−a)/b)+1]⁻¹, (10)

where N is the solution number density, to determine a and b. N_{co} was solved using N_{co}=a+bLn (1/f−1) setting f=0.95 or 0.99 for 5% or 1% aggregation, respectively, to quantify the value of the cut off concentration. Eq. 2 (with n=1) was divided by the cut off concentration determined here to find α. For dimers and trimers, the concentration of the maxima in plots of the fractional yield was determined versus concentration using quadratic fitting in the vicinity of the peak and divide the concentration from Eq. 2 (for n=2 and 3, respectively) by this concentration from simulation to determine a for these cases.

Results

The QD clusters at the focus of this study are formed in a multistep process. First, the QD clusters are formed or fabricated as individual nanoparticles trapped within an evaporating droplet combine. Then the QD clusters are separated based on their size within a DMA before electrostatic deposition onto a substrate. Here, Monte Carlo simulations were used to elucidate the influence of several parameters on the cluster yield and selectivity. Selectivity or purity is defined as the fraction of the clusters exiting the DMA or deposited electrostatically that are of the desired composition. The spatial distribution of the nanoparticles in solution along with the mean and standard deviation of the nanoparticle and electrospray droplet size distributions govern the nanoparticle yield and purity. The values of these parameters were identified that maximize the yield of a particular cluster type or prevent clustering altogether.

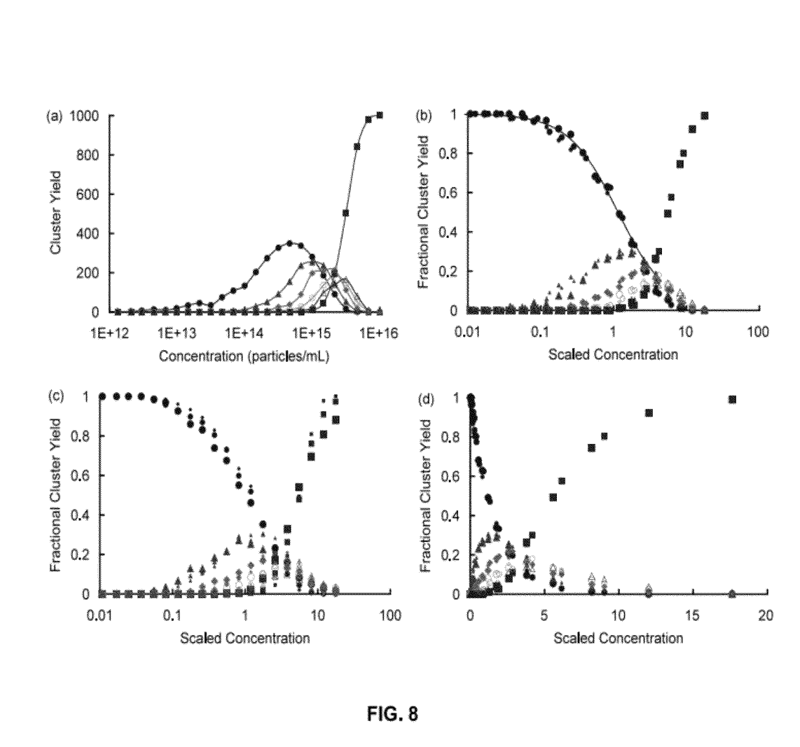

FIG. 8 displays simulations of the total and fractional yield of clusters formed at various droplet diameters and concentrations. FIG. 8a shows that at low concentrations the 1000 droplets used in the simulation capture very few particles because the solution is dilute. As the concentration increases, individual particles (termed monomers) are captured within the droplets. Further increases in the concentration lead to significant capture of two or more particles per droplet, which then form into clusters. At a concentration of approximately 7×10¹⁴ particles/mL for 150 nm droplets, FIG. 8a shows that the monomer yield achieves a maximum (an optimal concentration at which to operate the DMA). As the concentration rises further the dimers, trimers, tetramers, and pentamers each successively dominate the distribution with decreasing concentration intervals. Finally, at even higher concentrations essentially all of the clusters are composed of six or more particles.

FIG. 8b displays the fractional yield in scaled terms. The fractional yield represents the individual yield for a specific type of cluster divided by the sum of all cluster yields, and the scaled concentration is the actual concentration divided by the characteristic concentration scale given as Eq. 2 (with n=α=1). Scaling causes each of the curves to fall on each other. It was found that, regardless of the droplet diameter, all of the simulation results lie within a narrow band; no inherent order was observed within the band of uncertainties. This indicates that two factors controlling the yield of a particular type of cluster (or avoiding it altogether) are the nanoparticle concentration and the droplet diameter. In dimensional terms this means that larger droplets increase the yield. FIG. 8c shows that the width of the droplet distribution plays only a minor role. Clusters form at marginally smaller concentrations as the droplet standard deviation, σ_{drop}, increases because droplets big enough to capture particles are included in the distributions of droplets with smaller average sizes. Neither the nanoparticle diameter nor the standard deviation significantly influence the fractional yield.

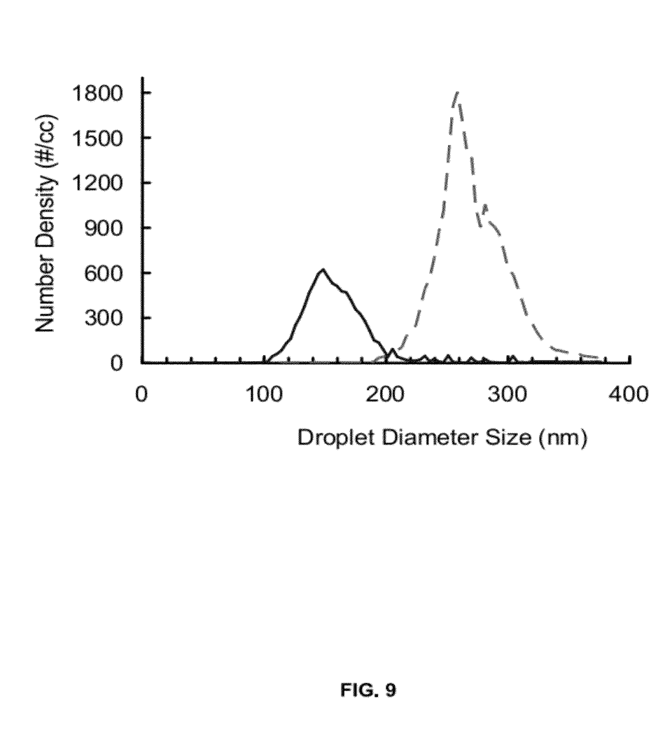

Notably, the figures indicate the conditions under which the yield of a particular type of cluster can be maximized or minimized. Controlling the nanoparticle concentration is through dilution or concentration. The droplet size distribution is governed, at least partially, by the solution ionic strength/conductivity, the capillary diameter, the solution surface tension, electrospray flow rates, solution viscosity, and the electrospray flow regime. FIG. 9 shows droplet size distributions obtained from a 25 micron inner diameter capillary operated in the stable cone-jet regime as a function of the solution ionic strength. The figure shows that the droplet diameter decreases as the ionic strength of the solution increases. Indeed, the mean diameter decrease from over 250 nm at 2 mM ammonium acetate to less than 150 nm at 20 mM ammonium acetate, while the width of the droplet distribution remains a nearly constant fraction of the droplet diameter. For this reason, the standard deviation of the droplet diameter in most simulations was selected to be approximately ⅙ of the droplet diameter.

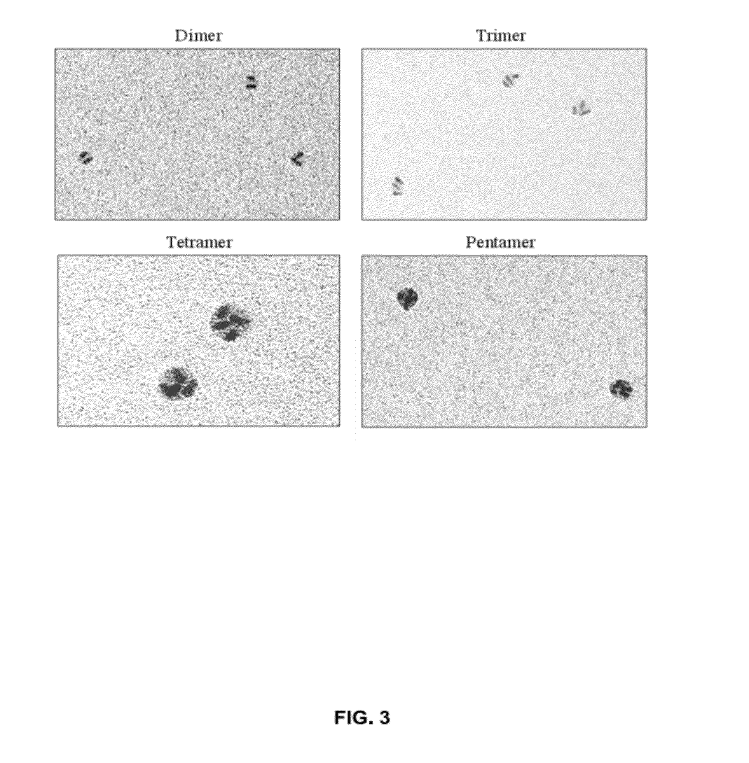

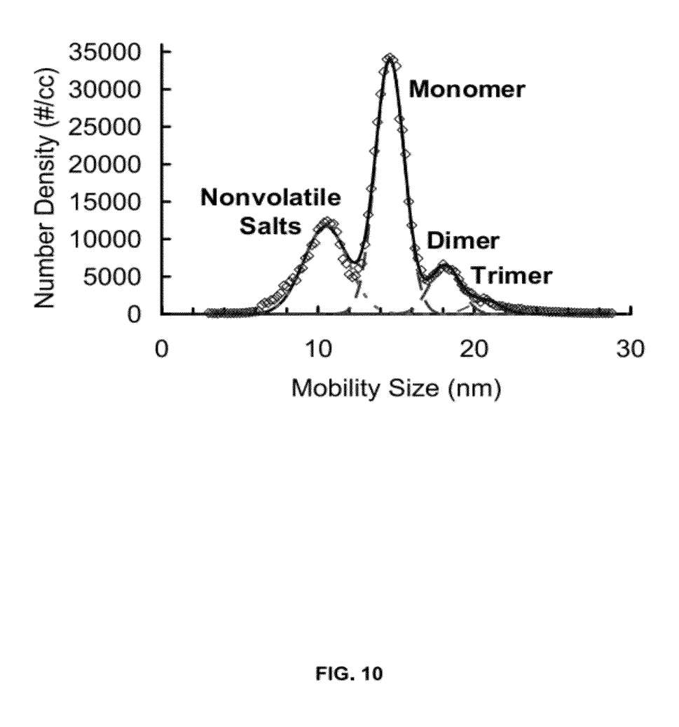

To validate the simulations, FIG. 10 shows a typical ES-DMA size distribution for QDs at a concentration of 2.4×10¹⁴ particles/mL. These QDs are composed of a CdSe core, a ZnS shell, and an organic layer with a carboxylic terminus (see FIG. 3). The ES-DMA measures a size of 14.4 nm (Pease et al. 2010). The salt shell is approximately 2.4 nm thick leaving the core, shell and organic layers to be 12.0 nm. This size is slightly larger than that measured using TEM because DMA measures the aerodynamic drag including that from the organic layers, not simply the electron rich core and shell. This size distribution was fit and integrated over the Gaussian distributions to find that monomers, dimers, and trimers represent 79.3%, 15.7%, and 4.54% of the distribution, respectively. This is in reasonable agreement with the results of FIG. 6b, where a concentration of 2×10¹⁴ particles/mL has a composition of 80.2%, 16.4%, and 3.34%, respectively. The excellent agreement (a difference of ˜1%, which is well within measurement uncertainty) provides qualitative and quantitative validation of the computation results.

The results of FIG. 8 are summarized by developing a semiempirical relationship (see Eq. 2). This relation was developed by Pease, et al., who recognized the need to differentiate aggregates that had formed in solution versus those that were formed in the electrospray droplet (Pease et al. 2008). They asserted that if the concentration remained well below the cut-off concentration, aggregates detected using ES-DMA-CPC would represent those formed in solution. Using this logic, they determined the concentration can remain below 5.7×10¹⁴ particles/mL for 150 nm droplets. However, their calculation incorrectly assumed that each antibody is equally spaced from every other antibody. Furthermore, FIG. 8a shows that at 5.7×10¹⁴ particles/mL approximately 20% of the clusters are dimers. This significant deviation justifies their requirement that the concentration may remain less than Nₛ and establishes the need for more rigorous determination of N_{co}.

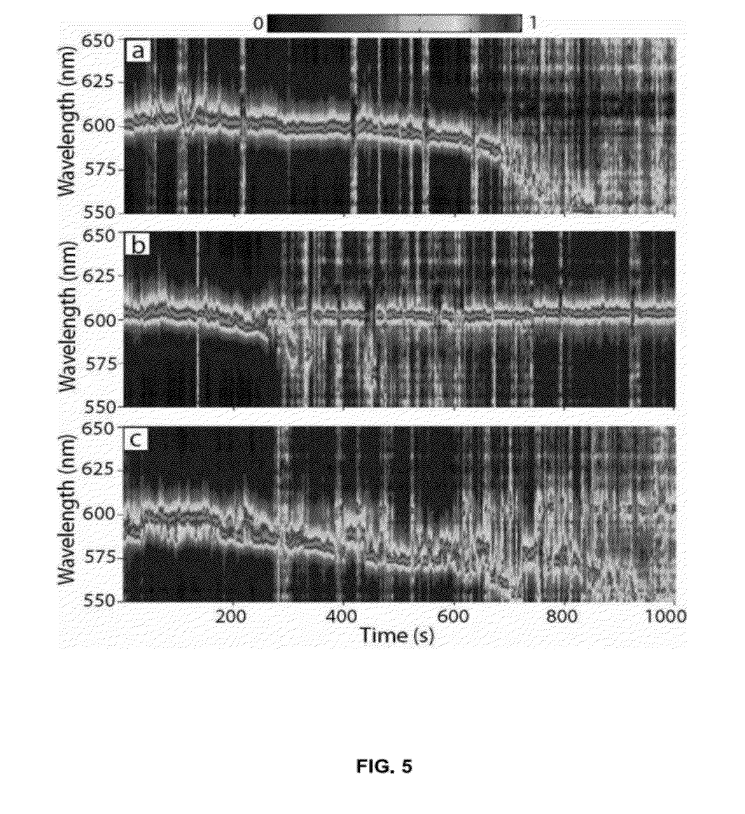

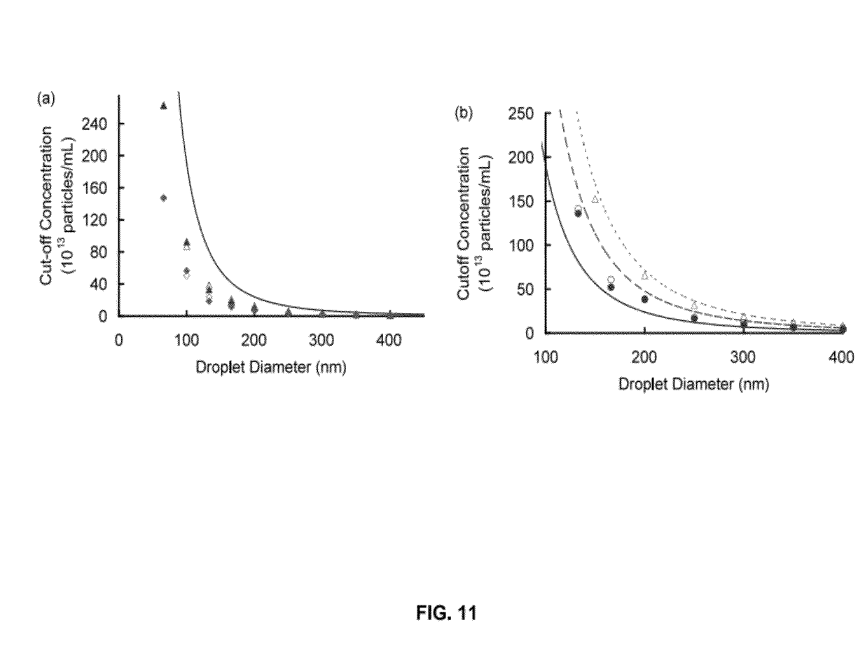

To make this determination, the curves in FIG. 11 and other simulation runs were fit, to find that α=2.13±0.18 (one standard deviation) and 3.51±0.45 for the 5% and 1% level, respectively. Values of 5% and 1% are appropriate because they reflect the requirements of the pharmaceutical industry to minimize protein aggregation and because there is a modest amount of uncertainty associated with single particle counting using the CPC. The narrow standard deviation confirms the form of Eq. 2, particularly the d_{drop}⁻³ dependence (see FIG. 11), as anticipated in the overlap of scaled curves in FIG. 5. Similarly, narrow standard deviations are obtained if σ_{drop}/d_{drop} is allowed to vary from 0 to ⅙. Then α=2.29±0.15 and 3.84±0.38, respectively. Although there does appear to be a modest trend towards larger α with increasing variability in droplet diameter, the overlap between standard deviations indicates that the trend is not sufficient to achieve significance (see FIG. 11c). The magnitude of α indicates that dimers and other clusters begin to appear at concentrations well below what would be expected from Nₛ. Yet, a value of 2-4 is not unexpected from scaling analysis and the scaling law was successful in that it predicted the answer well within 1 order of magnitude as required. Nevertheless, quantitative determination of the N_{co} accounts for the spatial and size distributions not otherwise anticipated from scaling theory alone.

FIG. 11b compares the concentration corresponding to the maxima of the dimers and trimers to N_{co} (see Eq. 2 for α=1) for monomers (n=1), dimers (n=2) and trimers (n=3). Remarkably, the scaling relation of Eq. 3 is more predictive for the maxima of the dimers and trimers. For dimers (n=2) α=1.30±0.09 and for trimers (n=3) α is only 1.10±0.04. These values are consistent with FIGS. 6b, c, and d where the peaks occur at n/α, and can be used to estimate the desired concentration to optimize the yield of particular types of clusters.

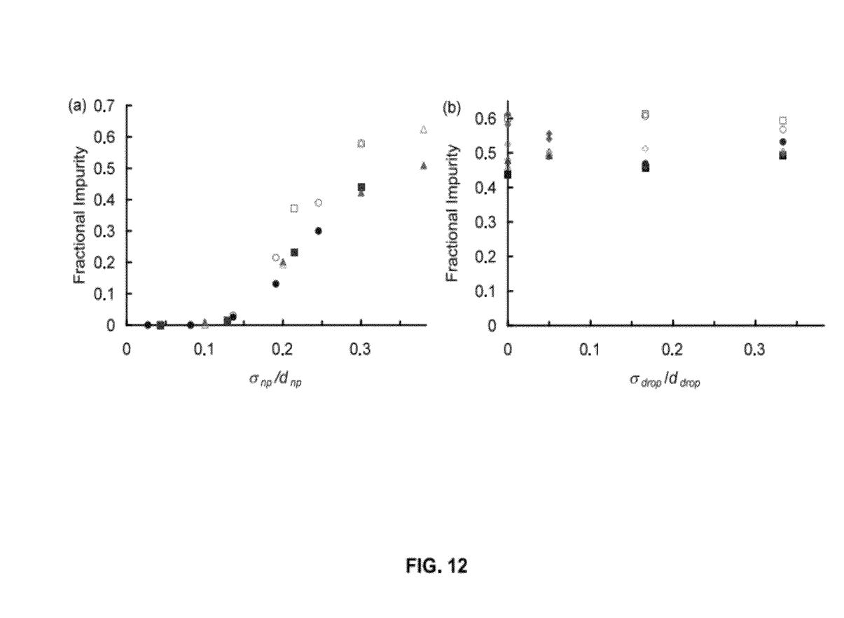

The second focus of this example is to determine how the selectivity depends on the spatial distribution of the nanoparticles in solution and the mean and standard deviation of the nanoparticle and electrospray droplet size distributions. Selectivity of particles exiting the DMA determines the purity of clusters that are deposited electrostatically on TEM grids or other substrates for further analysis. Although the DMA has subnanometer resolution, overlap of the various components in the ES-DMA-CPC size distribution leads directly to deposition of impurities (i.e. clusters other than the one desired). To estimate the impurity level, simulation data were fit with Gaussian curves to determine the maximum, width, and mean of the distribution (see FIG. 7) of each type of cluster. The overlap was calculated of neighboring peaks on dimer and trimer selectivity as per Eq. 9. FIG. 12 shows how the overlap depends on the nanoparticle distribution, droplet distribution, and concentration. Nanoparticle sizes from 6 nm to 22 nm were selected because they span the relevant size range for QDs and proteins and exceed the DMA's lower limit of quantitation (LoQ=5 nm).

FIG. 12a shows an important parameter in determining the selectivity to be σₙₚ/dₙₚ. When σₙₚ/dₙₚ (equivalent to the nanoparticles' coefficient of variation) is small (<0.13) neighboring peaks in the size distribution do not overlap significantly, but as σₙₚ/dₙₚ increases peak overlap increases and the impurity level rises sharply. Although the selectivity may depend modestly on nanoparticle shape as this affects peak separation, the sharp rise in impurity with σₙₚ/dₙₚ holds regardless of nanoparticle morphology (Pease et al. 2008). In contrast, the purity depends only weakly on σ_{drop}/d_{drop} as shown in FIG. 12b.

The occurrence of a single curve summarizing all of the simulation data in FIG. 12a provides a powerful means of screening potential nanoparticles as candidates for clustering. Ideally σₙₚ/dₙₚ will remain less than 13% and this can be achieved with highly monodispersed nanoparticle synthesis.

The simulations indicate at least two “knobs” with which to tune the yield and the selectivity. As summarized in Table 1, the yield can be controlled by the droplet diameter and nanoparticle concentration, whereas the selectivity can be controlled by the nanoparticle size distribution. Because the parameters form independent sets, the selectivity and yield can be controlled separately and optimized independently.

TABLE 1
Summary of parameters affecting yield and selectivity

| Parameter | Yield | Dimer Selectivity |
|---|---|---|
| Concentration | Strong | Negligible |
| Average Droplet Diameter | Strong | Weakly |
| Droplet Diameter Standard Deviation | Weak | Weakly |
| Average Particle Diameter | Negligible | Modestly |
| Particle Diameter Standard Deviation | Negligible | Strong |

### Example 2

In this example, groups of monomers, dimers, trimers, tetramers, or pentamers of CdSe/ZnS QD clusters were preferentially produced on different substrates using REDICAP. QD solutions containing individual COOH surface functionalized cadmium selenide (CdSe) core and zinc sulfide (ZnS) shell core-shell QDs (605 nm emission peak, Invitrogen, Carlsbad, Calif.) were electrosprayed using an electrospray aerosol generator (TSI Inc., Shoreview, Minn., #3480) through a nominally 25 μm inner diameter capillary with a tapered outlet. The stable cone-jet condition was obtained by varying the electrospray voltage from 0.2 kV to 3.6 kV and confirmed by monitoring both the current and visual appearance of the meniscus at the capillary tip. Electrospray sheath gas flow rates were 0.2 L/min of CO₂ and 1.0 L/min of air. Droplets containing the QDs were stabilized by passage through a bipolar charge neutralizer in which a Po-210 source reduced the charge on the droplet as described in detail by Wiedensohler using a modified Boltzmann distribution. Droplets dry as they pass through the neutralizer chamber and approximately 1.0 m of plastic Tygon tubing (1.6 cm diameter) connecting the exit of the ES to the entrance of the DMA. The clusters form as the droplet dries. The DMA acted like a band-pass filter that for a given electrode voltage and gas flow rate enables a narrow size band of ions to be purified and exit for further analysis. The DMA operated with sheath gas flow rate of 30 L/min of nitrogen gas in an annular analysis chamber (TSI Inc., #3080). Electrostatic potentials as strong as −10 kV deflected positively charged particles toward collection slits at the distal end of the chamber. Because a negative bias was applied to aerosolized ions within the DMA, only nanoparticles that acquire a positive charge were detected (the fraction with positive charge is known and does not adversely bias the distribution). The monodispersed flow exiting the analysis chamber can be either counted using a condensation particle counter or deposited on surfaces for additional analysis. For counting, the CPC (TSI Inc., #3025A) operates at 1.5 L/min, so the 1.0 L/min flow exiting the DMA is supplemented by 0.5 L/min of ambient air filtered through a HEPA filter. Within the CPC, particles passed through a saturated butanol environment and grew into droplets several microns in size, which can be counted individually as they obscure light impinging on a photodetector. The CPC reported the number of particles passing the detector per unit time after averaging for 20 s to minimize any transient responses. By varying the voltage in the DMA, nanoclusters in the range of interest in 0.2 nm increments were measured. Conversion to size was performed assuming the particles to be spheres with a Cunningham slip correction factor of C_{c=1}+Kn (α+βexp(γ/Kn)), where Kn=2λ/d, d is the particle's diameter, α=1.257, β=0.40, γ=1.110, and the gas mean free path at room temperature is λ=66 nm. The mean or number-average diameter is calculated as d=ΣᵢdᵢNᵢ/ΣᵢNᵢ, where Nᵢ is the number of particles counted by the CPC of size dᵢ. Monomer QDs and dimer and trimer QD clusters were identified in size distributions. Based on this analysis, the DMA voltage was set to that corresponding to peaks corresponding to monomers, dimers, etc. They were then passed into an electrostatic deposition chamber (TSI, Inc., #3089) at a flow rate of 1.0 L/min-1.5 L/min under an electrostatic potential of −10 kV for a variable amount of time. The deposition time onto holey polymer-coated carbon TEM grids was selected to ensure that the product of the aerosol number density and time exceeded 3000 particle.hr/cc. For deposition onto cover slips pretreated in KOH and UVO-cleaner (Jelight Co.), this product appeared to be optimal at approximately 100 particle·hr/cc. FIG. 3 shows exemplary structures of clusters containing two, three, four or five particles produced by the REDICAP technique. Clusters were purified by selecting those of a particular aerodynamic size. These samples were then analyzed with an integrated confocal microscope that measures the fluorescence intermittency, spectral diffusion, and dynamic fluorescence lifetime of a single QD or an individual QD cluster—all simultaneously from one instrument package. For optical characterization, a picosecond laser is coupled to a confocal microscope to excite QDs on a substrate which is mounted on an X, Y, Z translation stage with subnanometer precision. After the distribution of QDs is imaged, the confocal beam is repositioned over a target single QD or a cluster of QDs to simultaneously measure the fluorescence intermittency, dynamic emission spectra and fluorescence lifetime.

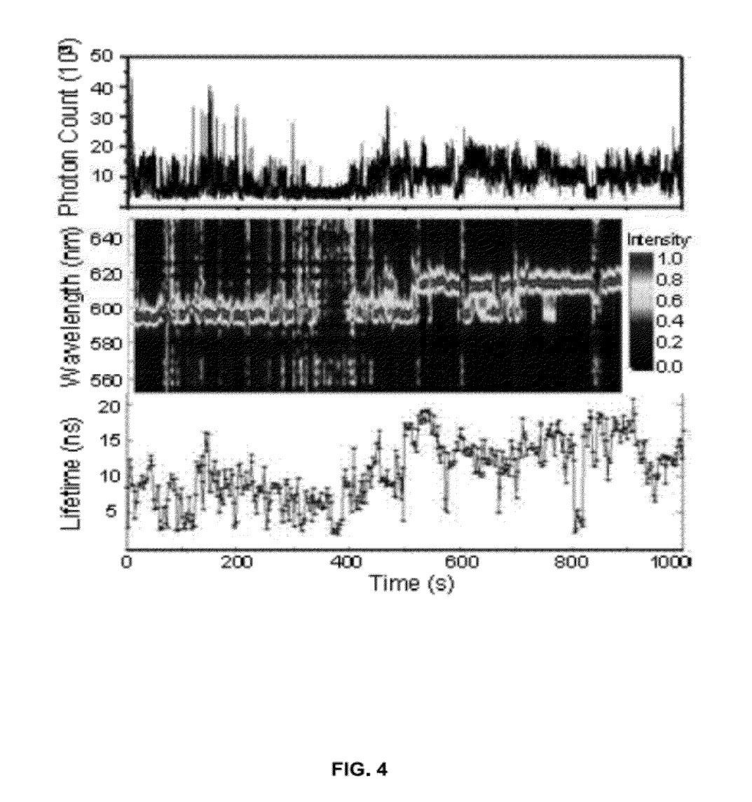

The results on a dimer of CdSe/ZnS QD rods reveal the dynamic, quantum mechanical details of two QDs interacting in nanoscale proximity (FIG. 4). The time evolution of the fluorescence emission intensity, fluorescence emission spectra, and fluorescence lifetime are simultaneously obtained on a dimer of QDs, providing information on how the QDs interact. The intensity fluctuation exhibits two quantized levels indicative of the presence of two independently blinking QDs. The fluctuation in lifetime, commensurate with the intensity variation, confirms the existence of energy states by which exciton charge carriers momentarily undergo slow annihilation dynamics, resulting in a decrease in both the intensity and lifetime. Assembly of a pair of rod-shaped QDs with a certain relative dipole-dipole angle may allow for the control of emission wavelength of the combined system. These results suggest the potential for QD clusters to control the properties of photonic energy such as polarizability, spectrum, and delay in pulsed radiation. This technique may provide a platform to temporally control the pulsed photonic energy which can be employed in photonic gating devices such as gated photon counting detectors and optically gated field effect transistors.

### Example 3

This example addresses the skill in the art needed to determine the relative orientation of elongated QDs within a QD cluster. Specifically, in this example, the relationship between the mobility diameter and the angle between two otherwise identical QDs in a QD dimeric cluster was elucidated. As per equation 5 above, the mobility diameter measured in the DMA,

$${d}_{m} = {( \frac{\sqrt{π}}{6} {\sum }_{i = 1}^{3} \frac{1}{\sqrt{{A}_{i}}} )}^{- 1} , \qquad ( 5 )$$

depended on the projected areas. The orientation of QDs within a cluster affected the mobility diameter. For two particles in cluster the three relevant projected areas orthogonal to the principle axes of the cluster as determined by symmetry conditions are

A₁=2dl

A₂=2dl Sin [θ/2]+π/2d² Sin [(π−θ)/2]

A₃=2dl Cos [θ/2]+π/4d² Cos [(π−θ)/2]. (11)

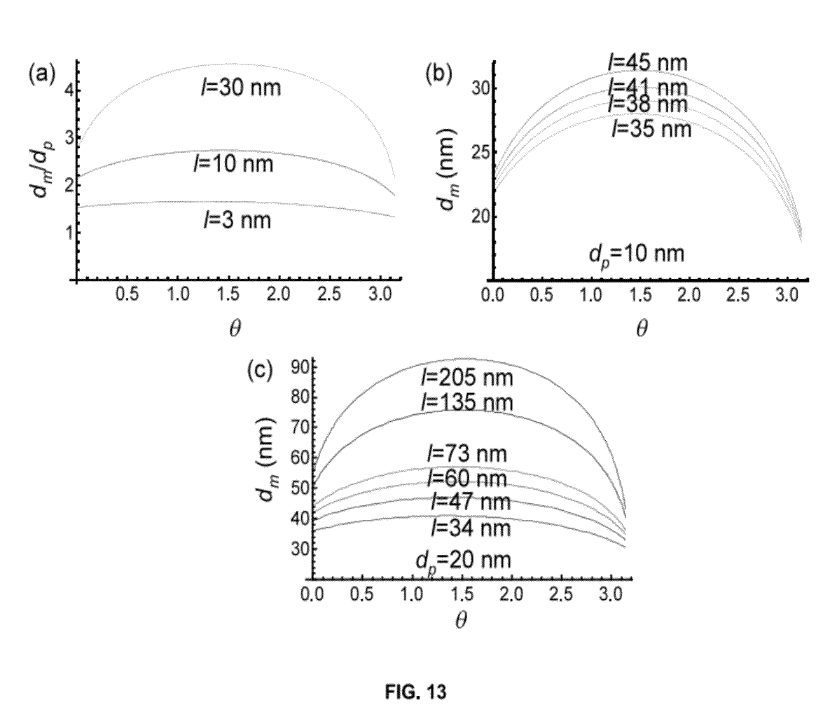

As the angle between the two quantum dot changes, so did the projected area and hence the mobility diameter. FIG. 13 shows that the mobility diameter increases from θ=0 to θ=π/2, achieves a maximum at θ=π/2 and then declines from θ=π/2 to θ=π. Due to symmetry considerations angles greater than Tr merely repeat the results of those below π. θ=0 and θ=π correspond to parallel and collinear QD orientations, where as θ=π/2 corresponds to perpendicular orientations. Therefore for a given homodimer peak, a portion of the size distribution below the peak corresponds to a mixture of orientations more closely approximating collinear or parallel configurations, where as the portion of the size distribution above the peak corresponds to configurations more closely resembling perpendicular orientations of the QDs. The DMA has the ability to select from size distributions with a width of ≦6 nm and FIG. 10 shows dimers to have a width of at least 3.0 nm, which is more than sufficient to distinguish orientations of many dimeric clusters. The figure also shows that increasing the diameter or length of the QD composing the cluster leads to larger differences in size between the perpendicular and parallel configurations. However larger particle sizes decrease quantum confinement suggesting that for core only QDs without shell, there may be an optimum QD size balancing both aspects. For QDs with shell or organic coating the confinement diameter and external diameter decouple allowing significantly additional flexibility.

### Example 4

This example describes the preparation of heterogeneous QD clusters consisting of heterodimers. Here solutions of two distinct QDs are each sized using ES-DMA with CPC or electrometer detection. The peak locations are noted both in size and concentration. The higher concentration QD solution is diluted until the peaks for the individual QDs in both solutions are approximately identical, or the lower concentration QD solution is concentrated using a spin column until the peaks corresponding to individual QDs are approximately equal. The concentrations of both QDs should be low enough to avoid aggregation to minimize homodimer presence. It is preferable that the two quantum dot sizes be distinct and that the QD sizes be not too far different because in both extremes the heterocluster overlaps either the individual particle distribution or the homodimer distributions. The predicted sizes of homo and heterodimers can be predicted using Equation 5 with selection of suitable projected areas normal to the three orthogonal principle axes of the predicted heterodimer. The two solutions are mixed together 1:1 and electrosprayed. The heterodimer peak is detected in proximity to the predicted sizes. The heterodimer is electrostatically deposited onto TEM grids. The presence of the heterodimer is confirmed using TEM.

In a further example of the heterodimers, solutions of one QD and one gold nanoparticle of distinct sizes are each sized using ES-DMA with CPC or electrometer detection. The peak locations are noted both in size and concentration. The higher concentration solution is diluted until the peaks for both nanoparticles in both solutions are approximately identical or the lower concentration solution is concentrated using a spin column until the peaks corresponding to individual QDs are approximately equal. The concentrations of both QDs should be low enough to avoid aggregation to minimize homodimer presence. For metallic particles, the concentration should be low enough to minimize aggregation kinetics in solution on laboratory time scales. It is preferable that the two nanoparticle dot sizes be distinct and that the sizes be not too far different because in both extremes the heterocluster overlaps the either the individual particle distribution or the homodimer distributions. The predicted sizes of homo and heterodimers can be predicted using Equation 5 with selection of suitable projected areas normal to the three orthogonal principle axes of the predicted heterodimer. The two solutions are mixed together 1:1 and electrosprayed. The heterodimer peak is detected in proximity to the predicted sizes. The heterodimer is electrostatically deposited onto TEM grids. The presence of the heterodimer is confirmed using TEM.

### Example 5

In this example, a solar cell is described. The solar cell is prepared by assembling QD clusters and then electrostatically depositing them onto substrates. ED is preferential because the deposition is uniform and homogenous as opposed to deposition wherein a droplet is placed on a surface and coaxed to evaporate because QDs accumulate preferentially at contact lines. A preferred substrate is topologically patterned (e.g. on TiO₂ surface layers, layers of nanoparticles patterned or otherwise, nanotubes, carbon nanotubes, etc.). The preferred deposition density lies between 1.0×10⁷ particles/mm² and 1.0×10¹¹ particles/mm² in each layer. The required deposition time is Aρₛ(Q∈N_{g}), where A is the area, ρₛ is the required surface density, Q is the gas flow rate, and N_{g} is the gas phase particle density for overall or size selected particles, and ∈ is the deposition efficiency. The presence of QDs on the surface is confirmed by FTIR. The presence of a photovoltaic signal is confirmed by cyclic voltametry. The substrate so prepared is covered over with a conductive or electrolyte material. The conductive or electrolyte materials may comprise electron and hole conducting polymers, which are preferred because of their ability to transport dissociating excitons and provide intimate contact. For example, the conductive or electrolyte materials may include block copolymers that contain both electron transporting and hole transporting polymers, or redox polymers, or polymer electrolyte materials doped with carbon nanotubes or graphene. The final layer is a transparent conductive substrate, which may include indium tin oxide, FTO, doped tin oxide, metal (e.g. Pt) coated tin oxide, other transparent conductive oxides, or glasses supporting these materials. An antireflective coating may be applied and a back layer of up-converting glass may be applied. The solar cell is exposed to sunlight or photon source, and power is collected and measured.

In a further example, the substrate onto which the QD clusters are deposited is flexible. After deposition and filling with conductive materials a second flexible transparent substrate is applied. The flexible solar cell may be rolled or folded into a variety of shapes as desired.

In a further example, multiple layers of QD clusters are applied each with an intervening conductive carrier transport layer. The layers may each be identical, grouped into layers that are identical but different sets of layers can have different cluster compositions, or arranged in a gradient of cluster compositions or sizes to capture multiple wavelengths of photon energies.

### Example 6

QD clusters are prepared as discussed above and decorated with a binding molecule. Binding molecules include antibodies, PNA, lectins, etc. A substrate is prepared on which gold or other metal is deposited. The deposition may be a continuous film or nanoparticles, perhaps sintered together. The substrate surface is prepared with a thiolated capture antibody, where the thiolation is on the Fc element of the antibody. Prior to introduction of the antigen, the QD clusters absorb at a certain wave length and emit at a different wavelength. The difference in absorption and emission wavelengths allows the clusters to be detected without a background associated with the initial stimulation wavelength by time gating. Where the QD absorption wavelength is set to that of a QD having type II band alignment, the emission may also be time delayed allowing for further background decay. When the QD cluster approaches and binds to the antigen, the proximity to a metallic surface dampens the emission intensity. The difference between the signal without antigen, and that with it, is the indicator of antigen presence and concentration/density. In a further example, the QD clusters are encapsulated within a nanoparticle that is decorated with a binding molecule as before. The nanoparticle can be composed of a variety of different materials, for example, such as polymers or TEOS encapsulation because they are readily amenable to surface functionalization.

Any papers, manuscripts, texts, publications, patents, and patent applications disclosed herein are incorporated by reference in their entirety.

It will be obvious to those having skill in the art that many changes may be made to the details of the above-described embodiments without departing from the underlying principles of the invention. The scope of the present invention should, therefore, be determined only by the following claims.

1. A method of making at least one precision quantum dot cluster, the method comprising:
providing at least one aerosolized droplet with a desired droplet diameter size, the at least one aerosolized droplet comprising a solution of quantum dots in a desired concentration;
clustering together a desired number of the quantum dots within the at least one aerosolized droplet into at least one precision quantum dot cluster; and
separating the at least one precision quantum dot cluster according to a selected aerodynamic size, thereby making the at least one precision quantum dot cluster.

2. The method of claim 1, wherein the number of the quantum dots clustered together into the at least one precision quantum dot cluster is tuned by the droplet diameter size and the concentration of quantum dots in the solution.

3. The method of claim 1, wherein the at least one aerosolized droplet comprises a mean droplet diameter size between approximately 3 nm and approximately 40 microns.

4. The method of claim 1, wherein the at least one aerosolized droplet comprises a mean droplet diameter size of at least one of 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 35 nm, 40 nm, 45 nm, 50 nm, 75 nm, 100 nm, 150 nm, 200 nm, 250 nm, 300 nm, 350 nm, 400 nm, 450 nm, 500 nm, 550 nm, 600 nm, 650 nm, 700 nm, 750 nm, 800 nm, 850 nm, 900 nm, 1 micron, 5 microns, 10 microns, 15 microns, 20 microns, 25 microns, 30 microns, 35 microns, and 40 microns.

5. The method of claim 1, wherein the concentration of quantum dots in the solution ranges from approximately 3×10⁷ particles/mL to approximately 2×10¹⁸ particles/mL.

6. The method of claim 1, wherein the concentration of quantum dots in the solution is at least one of 3×10⁷ particles/mL, 5×10⁷ particles/mL, 7×10⁷ particles/mL, 9×10⁷ particles/mL, 1×10⁸ particles/mL, 1×10⁹ particles/mL, 1×10¹⁰ particles/mL, 1×10¹¹ particles/mL, 1×10¹² particles/mL, 1×10¹³ particles/mL, 1×10¹⁴ particles/mL, 1×10¹⁵ particles/mL, 1×10¹⁶ particles/mL, 1×10¹⁷ particles/mL, 1×10¹⁸ particles/mL, and 2×10¹⁸ particles/mL.

7. The method of claim 1, wherein the quantum dots in the solution comprise colloidal quantum dots and are induced to cluster by evaporating the aerosolized droplet.

8. The method of claim 1, wherein the quantum dots in the solution are selected from at least one of the following: type-I band alignment quantum dots, type-II band alignment quantum dots, upconverting quantum dots, semiconducting quantum dots, core only quantum dots, core-shell quantum dots, and combinations thereof.

9. The method of claim 1, wherein the at least one precision quantum dot cluster comprises at least one of a quantum dot dimer, a quantum dot trimer, quantum dot tetramer, quantum dot pentamer, quantum dot hexamer, or quantum dot heptamer.

10. The method of claim 1, wherein the at least one precision quantum dot cluster comprises at least one of a homodimer or a heterodimer.

11. The method of claim 1, wherein the at least one precision quantum dot cluster comprises a homodimer comprising a pair of quantum dots selected from at least one of the following: a pair of core only quantum dots, a pair of core-shell quantum dots having type-I band alignment, a pair of core-shell quantum dots having type-II band alignment, a pair of semiconducting quantum dots, and a pair of upconverting quantum dots.

12. The method of claim 1, wherein the at least one precision quantum dot cluster comprises a heterodimer comprising a combination of two different quantum dots selected from the group consisting of core only quantum dots, core-shell quantum dots, quantum dots having type-I band alignment, quantum dots having type-II band alignment, semiconducting quantum dots, and upconverting quantum dots.

13. The method of claim 1, wherein the quantum dots in the solution comprise a chemical composition selected from at least one of CdS, CdSe, CdTe, InP, GaAs, GaP, GaN, GaInP, core-shell InP/ZnCdSe₂, Ge, Si PbSe, PbS, PbTe, core-shell CdTe/CdSe, core-shell CdSe/ZnS, InSb, and InAs.

14. The method of claim 1, wherein the at least one precision quantum dot cluster is deposited on a substrate.

15. At least one precision quantum dot cluster with a selected composition, the at least one precision quantum dot cluster comprising:
at least one quantum dot multimer selected from at least one of a quantum dot dimer, a quantum dot trimer, a quantum dot tetramer, a quantum dot pentamer, a quantum dot hexamer, or a quantum dot heptamer.

16. The at least one precision quantum dot cluster of claim 15, wherein the quantum dot multimer comprises at least two quantum dots selected from the group consisting of core only quantum dots, core-shell quantum dots, quantum dots having type-I band alignment, quantum dots having type-II band alignment, upconverting quantum dots, semiconducting quantum dots, and combinations thereof.

17. The at least one precision quantum dot cluster of claim 15, wherein the composition of the precision quantum dot cluster may be selected according to a method comprising:
providing at least one aerosolized droplet with a desired droplet diameter size, the at least one aerosolized droplet comprising a solution of quantum dots in a desired concentration;
clustering together a desired number of the quantum dots within the at least one aerosolized droplet into at least one precision quantum dot cluster; and
separating the precision quantum dot clusters according to a selected aerodynamic size, thereby making the at least one precision quantum dot cluster.

18. The at least one precision quantum dot cluster of claim 16, wherein the number of the quantum dots clustered together into the at least one precision quantum dot cluster is tuned by the droplet diameter size and the concentration of quantum dots in the solution.

19. The at least one precision quantum dot cluster of claim 15, wherein the at least one quantum dot multimer comprises a homodimer.

20. The at least one precision quantum dot cluster of claim 15, wherein the at least one quantum dot multimer comprises a heterodimer.

21. A photovoltaic device comprising a precision dot cluster of claim 15.
